(19) United States
(12) Patent Application Publication
(10) Pub. No.: US 2024/0258176 A1
(43) Pub. Date: Aug. 1, 2024

(54) SEMICONDUCTOR DEVICE AND METHOD FOR MANUFACTURING THE SAME

(71) Applicant: SAMSUNG ELECTYRONICS CO., LTD., Suwon-si (KR)

(72) Inventors: Jin Bum KIM, Suwon-si (KR); Sang Moon Lee, Suwon-si (KR)

(21) Appl. No.: 18/369,242

(22) Filed: Sep. 18, 2023

(30) Foreign Application Priority Data
Jan. 26, 2023 (KR) 10-2023-0010072

(51) Int. Cl. H01L 21/8238; H01L 27/092; H01L 29/06; H01L 29/417; H01L 29/423; H01L 29/66

(52) U.S. Cl. CPC H01L 21/823807; H01L 21/823814; H01L 21/823871; H01L 27/092; H01L 29/0673; H01L 29/41733; H01L 29/42392; H01L 29/66439; H01L 29/66545

(57) ABSTRACT

A method for manufacturing a semiconductor device includes providing a buffer substrate, forming a sacrificial contact film on the buffer substrate, forming a sacrificial contact pattern by patterning the sacrificial contact film, forming a first base layer on the buffer substrate that surrounds the sacrificial contact pattern, forming an active pattern on the first base layer and the sacrificial contact pattern that extends in a first direction, forming a gate electrode on the active pattern extending in a second direction intersecting the first direction, forming a source/drain pattern on a side surface of the gate electrode for connection to the active pattern. The source/drain pattern overlaps the sacrificial contact pattern in a third direction intersecting the first and second directions. The sacrificial contact pattern is exposed by removing the buffer substrate. A lower source/drain contact is formed for connection to the source/drain pattern by replacing the exposed sacrificial contact pattern.

### CROSS-REFERENCE TO RELATED APPLICATION

This application claims priority under 35 U.S.C. § 119 to Korean Patent Application No. 10-2023-0010072, filed on Jan. 26, 2023 in the Korean Intellectual Property Office, the disclosure of which is incorporated by reference in its entirety herein.

### 1. TECHNICAL FIELD

The present disclosure relates to a semiconductor device and a method for manufacturing the same. More specifically, the present disclosure relates to a semiconductor device including a backside wiring pattern and a method for manufacturing the same.

### 2. DISCUSSION OF RELATED ART

Semiconductor devices have experienced increased importance in the electronics industry due to characteristics such as miniaturization, multifunctionality, and cost efficiency. The semiconductor devices may be classified into a semiconductor memory device that stores logic data, a semiconductor logic device that computes logic data, and a hybrid semiconductor device including a memory element and a logic element.

As the electronics industry develops, the demand for high reliability, high speed, and/or multifunctionality of the semiconductor device is increasing. Structures within the semiconductor device are becoming increasingly complex and highly integrated with each other to provide high reliability, high speed and multifunctionality.

### SUMMARY

A technical purpose of an embodiment of the present disclosure is to provide a semiconductor device with increased PPAC (power, performance, area, cost).

Another technical purpose of an embodiment of the present disclosure is to provide a method for manufacturing a semiconductor device having increased PPAC.

The technical purpose of embodiments of the present disclosure is not limited to the technical purpose as mentioned above, and other technical purposes as not mentioned will be clearly understood by those skilled in the art from descriptions set forth below.

According to an embodiment of the present disclosure, a method for manufacturing a semiconductor device, the method includes providing a buffer substrate. A sacrificial contact film is formed on the buffer substrate. A sacrificial contact pattern is formed by patterning the sacrificial contact film. A first base layer is formed on the buffer substrate. The first base layer surrounds the sacrificial contact pattern. An active pattern is formed on the first base layer and the sacrificial contact pattern. The active pattern extends in a first direction parallel to an upper surface of the first base layer. A gate electrode is formed on the active pattern. The gate electrode extends in a second direction intersecting the first direction and parallel to the upper surface of the first base layer. A source/drain pattern is formed on a side surface of the gate electrode. The source/drain pattern is directly connected to the active pattern. The source/drain pattern overlaps the sacrificial contact pattern in a third direction intersecting the first direction and the second direction and perpendicular to the upper surface of the first base layer. The sacrificial contact pattern is exposed by removing the buffer substrate. A lower source/drain contact is formed directly connected to the source/drain pattern by replacing the exposed sacrificial contact pattern.

According to an embodiment of the present disclosure, a method for manufacturing a semiconductor device includes providing a buffer substrate. A first base layer is formed on the buffer substrate. The first base layer includes a first surface facing the buffer substrate and a second surface opposite to the first surface. A sacrificial contact pattern is formed in the first base layer. The sacrificial contact pattern extends from the first surface towards the second surface. A width of the sacrificial contact pattern decreases as the sacrificial contact pattern gets closer to the second surface. An active pattern is formed on the second surface of the first base layer. The active pattern extends in a first direction parallel to an upper surface of the first base layer. A gate electrode is formed on the active pattern. The gate electrode extends in a second direction intersecting the first direction and parallel to the upper surface of the first base layer. A source/drain pattern is formed on a side surface of the gate electrode. The source/drain pattern is directly connected to the active pattern. The source/drain pattern overlaps the sacrificial contact pattern in a third direction intersecting the first direction and the second direction and perpendicular to the upper surface of the first base layer. The sacrificial contact pattern is exposed by removing the buffer substrate. A lower source/drain contact is formed that is directly connected to the source/drain pattern by replacing the exposed sacrificial contact pattern.

According to an embodiment of the present disclosure, a method for manufacturing a semiconductor device includes providing a buffer substrate. A sacrificial contact film is formed on the buffer substrate. A sacrificial contact pattern is formed by patterning the sacrificial contact film. A first base layer is formed surrounding a side surface of the sacrificial contact pattern. The first base layer includes a first surface facing the buffer substrate and a second surface opposite to the first surface. An active pattern is formed on the second surface of the first base layer. The active pattern extends in a first direction parallel to an upper surface of the first base layer. A gate electrode is formed extending in a second direction intersecting the first direction and parallel to the upper surface of the first base layer. The gate electrode penetrates the active pattern. A source/drain pattern is formed on a side surface of the gate electrode. The source/drain pattern is directly connected to the active pattern. The source/drain pattern overlaps the sacrificial contact pattern in a third direction intersecting the first direction and the second direction and perpendicular to the upper surface of the first base layer. A frontside wiring pattern is formed on the second surface of the first base layer. The frontside wiring pattern is electrically connected to the gate electrode and the source/drain pattern. The sacrificial contact pattern is exposed by removing the buffer substrate. A lower source/drain contact is formed that is directly connected to the source/drain pattern by replacing the exposed sacrificial contact pattern with a lower source/drain contact. A backside wiring pattern is formed on the first surface of the first base layer. The backside wiring pattern is directly connected to the lower source/drain contact.

### BRIEF DESCRIPTION OF DRAWINGS

The above and other aspects and features of the present disclosure will become more apparent by describing in detail some non-limiting embodiments thereof with reference to the attached drawings, in which:

FIG. 1 is an illustrative layout diagram for illustrating a semiconductor device according to an embodiment of the present disclosure.

FIG. 2 is a schematic cross-sectional view taken along A-A of FIG. 1 according to an embodiment of the present disclosure.

FIG. 3 is an enlarged view of the R area of FIG. 2 according to an embodiment of the present disclosure.

FIG. 4 is a schematic cross-sectional view taken along B-B of FIG. 1 according to an embodiment of the present disclosure.

FIG. 5 is a schematic cross-sectional view taken along C-C of FIG. 1 according to an embodiment of the present disclosure.

FIGS. 6 to 9 are various cross-sectional views for illustrating semiconductor devices according to some embodiments of the present disclosure.

FIGS. 10 to 29 are diagrams of intermediate structures corresponding to intermediate steps for illustrating a method for manufacturing a semiconductor device according to some embodiments of the present disclosure.

FIGS. 30 to 33 are diagrams of intermediate structures corresponding to intermediate steps for illustrating a method for manufacturing a semiconductor device according to some embodiments of the present disclosure.

FIGS. 34 and 35 are diagrams of intermediate structures corresponding to intermediate steps for illustrating a method for manufacturing a semiconductor device according to some embodiments of the present disclosure.

### DETAILED DESCRIPTION OF EMBODIMENTS

In the present disclosure, only MBCFET® including a multi-bridge channel is shown as an example of an electronic element included in a semiconductor device. However, this is only for convenience of explanation and embodiments of the present disclosure are not necessarily limited thereto. In an embodiment, the semiconductor device may include a tunneling transistor (tunneling FET), a vertical (FET VFET), a complementary FET (CFET), or a three-dimensional (3D transistor). Alternatively, the semiconductor device may include a bipolar junction transistor, a lateral double diffusion transistor (LDMOS), and the like.

Further, it will be understood that, although the terms “first”, “second”, “third”, and so on may be used herein to illustrate various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

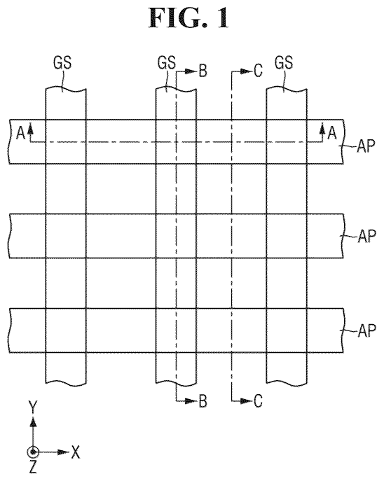

Hereinafter, referring to FIGS. 1 to 9, a semiconductor device according to some embodiments is described.

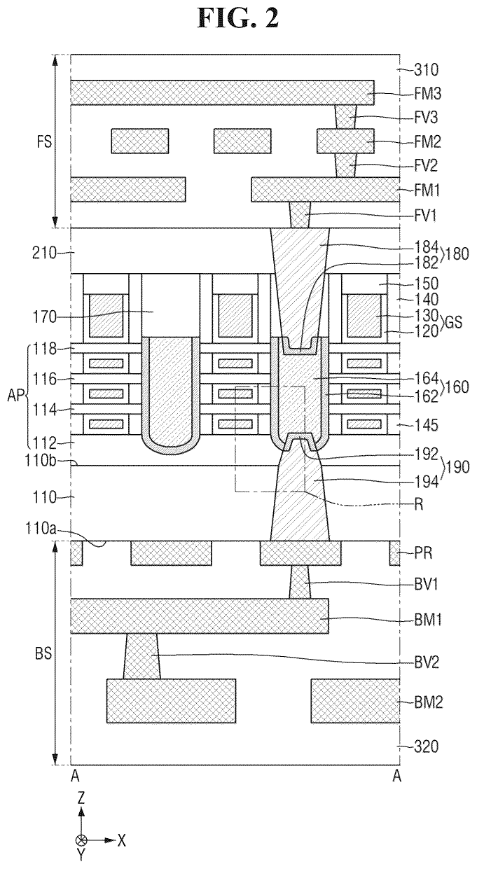

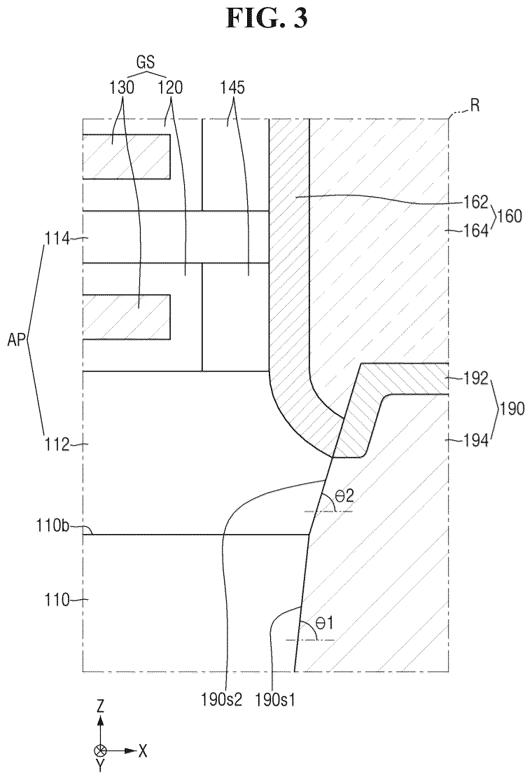

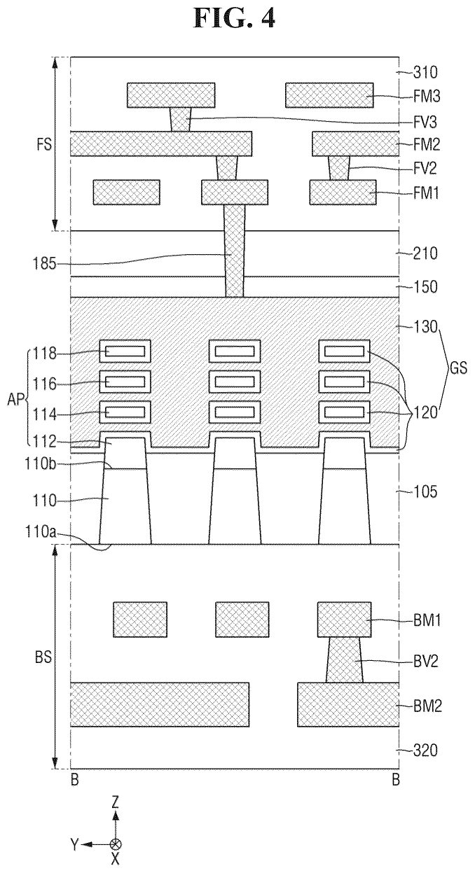

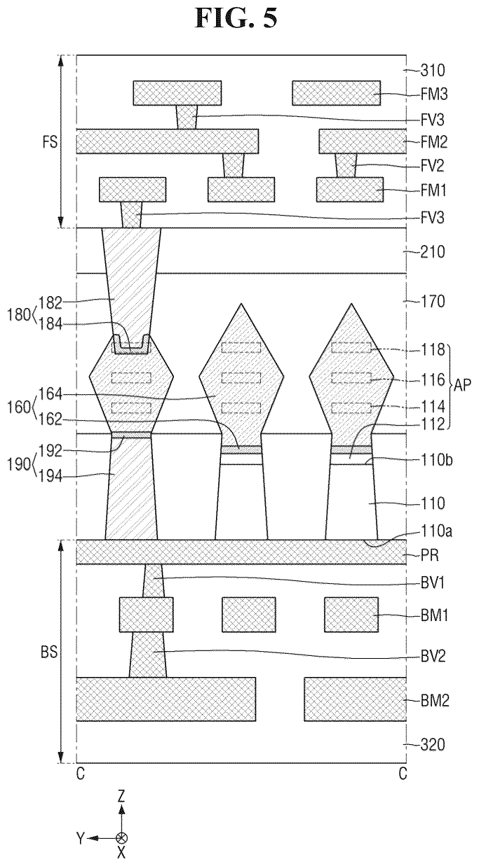

FIG. 1 is an illustrative layout diagram for illustrating a semiconductor device according to some embodiments. FIG. 2 is a schematic cross-sectional view taken along A-A of FIG. 1. FIG. 3 is an enlarged view to illustrate the R area of FIG. 2. FIG. 4 is a schematic cross-sectional view taken along B-B of FIG. 1. FIG. 5 is a schematic cross-sectional view taken along C-C of FIG. 1.

Referring to FIGS. 1 to 5, a semiconductor device according to some embodiments includes a first base layer 110, an active pattern AP, a field insulating film 105, a gate structure GS, a gate spacer 140, a gate capping pattern 150, a source/drain pattern 160, a first interlayer insulating film 170, a second interlayer insulating film 210, an upper source/drain contact 180, a frontside wiring structure FS, a lower source/drain contact 190, and a backside wiring structure BS.

In an embodiment, the first base layer 110 may include an insulating material. For example, the first base layer 110 may include at least one compound selected from silicon oxide, silicon oxynitride, silicon oxycarbonitride, and combinations thereof. However, embodiments of the present disclosure are not necessarily limited thereto. In an embodiment, the first base layer 110 may include a silicon oxide film.

The first base layer 110 may include a first surface 110a and a second surface 110b that are opposite to each other (e.g., in the third direction Z). For example, the first surface 110a may be a lower surface of the first base layer 110 and the second surface 110b may be an upper surface of the first base layer 110. As used herein, the first surface 110a may also be referred to as a backside of the first base layer 110, and the second surface 110b may be referred to as a frontside of the first base layer 110.

In some embodiments, the first base layer 110 may extend in an elongated manner in a first direction X. For example, as shown in FIG. 4, the first base layer 110 may include a plurality of fin patterns extending in the first direction X and arranged in a parallel manner to each other.

In an embodiment, a thickness of the first base layer 110 may be, for example, in a range of about 1 nm to about 500 nm. In this regard, thickness means a length in a third direction Z.

The active pattern AP may be formed on the second surface 110b of the first base layer 110. In an embodiment, the active pattern AP may extend in an elongated manner in the first direction X. Further, as shown in FIGS. 1 and 4, a plurality of active patterns AP may extend in the first direction X in a parallel manner to each other and may be spaced apart from each other in the second direction Y. The first and second directions X, Y may be parallel to an upper surface of the first base layer 110 and the third direction Z may be perpendicular to the upper surface of the first base layer 110.

In some embodiments, the active pattern AP may include a plurality of channel patterns (e.g., first to third channel patterns 114, 116, and 118) sequentially stacked on the first base layer 110 and spaced apart from each other (e.g., in the third direction Z) and extending in the first direction X. For example, the active pattern AP may include the first to third channel patterns 114, 116, and 118 sequentially stacked in the third direction Z intersecting the first and second directions X and Y. This active pattern AP may be used as a channel area of MBCFET® including a multi-bridge channel. However, the number of channel patterns included in the active pattern AP is only an example, and the active pattern AP may include two channel patterns or four or more channel patterns in some embodiments.

In some embodiments, the active pattern AP may further include a buffer layer 112. The buffer layer 112 may be interposed between the first base layer 110 and the channel patterns (e.g., the first to third channel patterns 114, 116, and 118). For example, in an embodiment, a lower surface of the buffer layer 112 may be disposed directly on the second surface 110b of the first base layer 110. However, embodiments of the present disclosure are not necessarily limited thereto. The buffer layer 112 may extend in the first direction X along an upper surface of the first base layer 110. The channel patterns (e.g., the first to third channel patterns 114, 116, and 118) may be spaced apart from the buffer layer 112 and may be sequentially arranged along the third direction Z. However, embodiments of the present disclosure are not necessarily limited thereto and the buffer layer 112 may be omitted in some embodiments.

In an embodiment, a thickness of the buffer layer 112 may be, for example, in a range of about 1 nm to about 500 nm. In this regard, the thickness means the length in the third direction Z.

In an embodiment, the active pattern AP may include an elemental semiconductor material such as silicon (Si) or germanium (Ge). In an embodiment, the active pattern AP may include a silicon pattern. Alternatively, the active pattern AP may include a compound semiconductor, for example, a group IV-IV compound semiconductor or a group III-V compound semiconductor. The group IV-IV compound semiconductor may include, for example, a binary compound including two compounds selected from carbon (C), silicon (Si), germanium (Ge), and tin (Sn), a ternary compound including three thereof, or a compound obtained by doping a group IV element thereto. The group III-V compound semiconductor may include, for example, a binary compound obtained by combining one compound selected from aluminum (Al), gallium (Ga), and indium (In) as a group III element and one compound selected from phosphorus (P), arsenic (As), and antimony (Sb) as a group V element with each other, a ternary compound obtained by combining two compounds selected from aluminum (Al), gallium (Ga), and indium (In) as a group III element and one compound selected from phosphorus (P), arsenic (As), and antimony (Sb) as a group V with each other, or a quaternary compound obtained by combining three compounds selected from aluminum (Al), gallium (Ga), and indium (In) as a group III element and one compound selected from phosphorus (P), arsenic (As), and antimony (Sb) as a group V with each other. However, embodiments of the present disclosure are not necessarily limited thereto.

In some embodiments, the buffer layer 112 may further contain high-concentration impurities. Such a buffer layer 112 may prevent a punch through phenomenon in the buffer layer 112. In an embodiment in which a field effect transistor including the active pattern AP and the gate structure GS is an NFET, the buffer layer 112 may contain a high-concentration p-type impurity. The p-type impurity may include, for example, at least one compound selected from B, C, In, Ga, Al, or combinations thereof. In an embodiment in which a field effect transistor including the active pattern AP and the gate structure GS is a PFET, the buffer layer 112 may contain a high concentration of n-type impurities. The n-type impurity may include, for example, at least one compound selected from P, Sb, As, or combinations thereof.

The field insulating film 105 may be formed on the first base layer 110. For example, as shown in FIG. 4 the field insulating film 105 may cover a side surface (e.g., a lateral side surface) of the first base layer 110. In some embodiments, the field insulating film 105 may cover at least a portion of a side surface of the buffer layer 112. Although it is illustrated in FIG. 4 that an upper portion of the buffer layer 112 protrudes from an upper surface of the field insulating film 105, embodiments of the present disclosure are not necessarily limited thereto. For example, in some embodiments, the upper surface of the field insulating film 105 may be coplanar with an upper surface of the buffer layer 112 (e.g., in the third direction Z).

In an embodiment, the field insulating film 105 may include, for example, at least one compound selected from silicon oxide, silicon nitride, silicon oxynitride, and combinations thereof. However, embodiments of the present disclosure are not necessarily limited thereto. In an embodiment, the field insulating film 105 may include a silicon oxide film.

The gate structure GS may be formed on the first base layer 110 and the field insulating film 105. Further, as shown in FIG. 1, the gate structure GS may intersect with the active pattern AP. For example, the gate structure GS may extend in an elongated manner in the second direction Y intersecting the first direction X. At least a portion of the active pattern AP may extend in the first direction X and extend through the gate structure GS. For example, each of the first to third channel patterns 114, 116, and 118 may extend in the first direction X and extend through (e.g., penetrate) the gate structure GS. The gate structure GS may surround each of the first to third channel patterns 114, 116, and 118. For example, the gate structure GS may completely surround each of the first to third channel patterns 114, 116, and 118.

The gate structure GS may include a gate dielectric film 120 and a gate electrode 130. The gate dielectric film 120 and the gate electrode 130 may be sequentially stacked on the active pattern AP.

The gate dielectric film 120 may be stacked on the active pattern AP. For example, the gate dielectric film 120 may extend along an upper surface of the buffer layer 112 and the upper surface of the field insulating film 105. Further, the gate dielectric film 120 may surround at least a portion of the active pattern AP. For example, the gate dielectric film 120 may extend around each of the first to third channel patterns 114, 116, and 118.

In an embodiment, the gate dielectric film 120 may include, for example, at least one compound selected from silicon oxide, silicon oxynitride, silicon nitride, and a high-k material having a higher dielectric constant than that of silicon oxide. The high dielectric constant (high-k) material may include, for example, at least one compound selected from hafnium oxide (HfO₂), zirconium oxide (ZrO₂), lanthanum oxide (La₂O), aluminum oxide (Al₂O₃), titanium oxide (TiO₂), strontium titanium oxide (SrTiO₃), lanthanum aluminum oxide (LaAlO₃), yttrium oxide (Y₂O₃), hafnium oxynitride (HfOₓN_{y}), zirconium oxynitride (ZrOᵣN_{y}), lanthanum oxynitride (La₂OₓN_{y}), aluminum oxynitride (Al₂OₓN_{y}), titanium oxynitride (TiOₓN_{y}), strontium titanium oxynitride (SrTiOₓN_{y}), lanthanum aluminum oxynitride (LaAlOₓN_{y}), yttrium oxynitride (Y₂OₓN_{y}) and combinations thereof. However, embodiments of the present disclosure are not necessarily limited thereto.

The semiconductor device according to some embodiments may include an NC (negative capacitance) FET using a negative capacitor. For example, the gate dielectric film 120 may include a ferroelectric material film having ferroelectric properties and a paraelectric material film having paraelectric properties.

The ferroelectric material film may have negative capacitance, and the paraelectric material film may have positive capacitance. For example, in an embodiment in which two or more capacitors may be connected in series to each other, and capacitance of each of the capacitors has a positive value, a total capacitance is less than capacitance of each individual capacitor. On the contrary, when at least one of capacitances of two or more capacitors connected in series to each other has a negative value, a total capacitance may have a positive value and be greater than an absolute value of each individual capacitance.

In an embodiment in which the ferroelectric material film with negative capacitance and the paraelectric material film with positive capacitance are connected in series to each other, a total capacitance value of the ferroelectric material film and the paraelectric material film connected in series to each other may be increased. Using the increase in the total capacitance value, a transistor including the ferroelectric material film may have a subthreshold swing (SS) lower than about 60 mV/decade at room temperature.

The ferroelectric material film may have ferroelectric properties. In an embodiment, the ferroelectric material film may include, for example, at least one compound selected from hafnium oxide, hafnium zirconium oxide, barium strontium titanium oxide, barium titanium oxide, and lead zirconium titanium oxide. In this connection, in one example, hafnium zirconium oxide may refer to a material obtain by doping hafnium oxide with zirconium (Zr). In another example, hafnium zirconium oxide may refer to a compound of hafnium (H), zirconium (Zr), and oxygen (O).

The ferroelectric material film may further contain doped dopants. For example, in an embodiment the dopant may include at least one compound selected from aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr) and tin (Sn). A type of the dopant contained in the ferroelectric material film may vary depending on a type of the ferroelectric material included in the ferroelectric material film.

In an embodiment in which the ferroelectric material film includes hafnium oxide, the dopant contained in the ferroelectric material film may include, for example, at least one compound selected from gadolinium (Gd), silicon (Si), zirconium (Zr), aluminum (Al), and yttrium (Y).

In an embodiment in which the dopant is aluminum (Al), the ferroelectric material film may contain about 3 to about 8 at % (atomic %) of aluminum. In this connection, a content of the dopant may be a content of aluminum based on a sum of hafnium and aluminum.

In an embodiment in which the dopant is silicon (Si), the ferroelectric material film may contain about 2 to about 10 at % of silicon. In an embodiment in which the dopant is yttrium (Y), the ferroelectric material film may contain about 2 to about 10 at % yttrium. In an embodiment in which the dopant is gadolinium (Gd), the ferroelectric material film may contain about 1 to about 7 at % gadolinium. In an embodiment in which the dopant is zirconium (Zr), the ferroelectric material film may contain about 50 to about 80 at % zirconium.

The paraelectric material film may have paraelectric properties. The paraelectric material film may include, for example, at least one compound selected from silicon oxide and metal oxide having a high dielectric constant. In an embodiment, the metal oxide contained in the paraelectric material film may include, for example, at least one compound selected hafnium oxide, zirconium oxide and aluminum oxide. However, embodiments of the present disclosure are not necessarily limited thereto.

The ferroelectric material film and the paraelectric material film may include the same material. The ferroelectric material film may have ferroelectric properties, but the paraelectric material film may not have the ferroelectric properties. For example, in an embodiment in which each of the ferroelectric material film and the paraelectric material film includes hafnium oxide, a crystal structure of hafnium oxide contained in the ferroelectric material film is different from a crystal structure of hafnium oxide contained in the paraelectric material film.

The ferroelectric material film may have a thickness sized to exhibit ferroelectric properties. Although the thickness of the ferroelectric material film may be, for example, in a range of about 0.5 to about 10 nm, embodiments of the present disclosure are not necessarily limited thereto. Since a critical thickness exhibiting the ferroelectric properties may be vary based on a type of the ferroelectric material, the thickness of the ferroelectric material film may vary depending on the type of the ferroelectric material.

In an embodiment, the gate dielectric film 120 may include one ferroelectric material film. However, in some embodiments the gate dielectric film 120 may include a plurality of ferroelectric material films spaced apart from each other. In an embodiment, the gate dielectric film 120 may have a multilayer structure in which a plurality of ferroelectric material films and a plurality of paraelectric material films are alternately stacked on top of each other.

The gate electrode 130 may be stacked on the gate dielectric film 120. For example, the gate dielectric film 120 may be interposed between the active pattern AP and the gate electrode 130. The gate dielectric film 120 may be interposed between the field insulating film 105 and the gate electrode 130. The gate electrode 130 may be formed using, for example, a replacement process. However, embodiments of the present disclosure are not necessarily limited thereto.

Although the gate electrode 130 is shown as a single film, embodiments of the present disclosure are not necessarily limited thereto, and the gate electrode 130 may be formed by stacking a plurality of conductive layers. For example, the gate electrode 130 may include a work function control film for adjusting a work function and a filling conductive film filling a space defined by the work function control film. The work function control layer may include, for example, at least one compound selected from TiN, TaN, TiC, TaC, TiAlC, and combinations thereof. The filling conductive film may include, for example, W or Al.

The gate spacer 140 may be formed on the first base layer 110 and the field insulating film 105. Further, the gate spacer 140 may extend along a side surface of the gate electrode 130. In some embodiments, a portion of the gate dielectric film 120 may be interposed between the gate electrode 130 and the gate spacer 140. For example, the gate dielectric film 120 may further extend along an inner side surface of the gate spacer 140. In an embodiment, such a gate dielectric film 120 may be formed by a replacement process. However, embodiments of the present disclosure are not necessarily limited thereto.

In an embodiment, the gate spacer 140 may include an insulating material, for example, at least one compound selected from silicon nitride, silicon oxynitride, silicon oxycarbide, silicon boron nitride, silicon carbonitride, silicon oxycarbonitride, and combinations thereof. However, embodiments of the present disclosure are not necessarily limited thereto. In an embodiment, the gate spacer 140 may include a silicon nitride film.

The gate capping pattern 150 may be formed on the gate structure GS. The gate capping pattern 150 may extend along an upper surface of the gate structure GS. It is shown in an embodiment of FIG. 2 that an upper surface of the gate capping pattern 150 is coplanar with an upper surface of the gate spacer 140. However, embodiments of the present disclosure are not necessarily limited thereto. For example, in an embodiment the gate capping pattern 150 may cover the upper surface of the gate spacer 140.

In an embodiment, the gate capping pattern 150 may include an insulating material, for example, at least one compound selected from silicon nitride, silicon oxynitride, silicon oxycarbide, silicon boron nitride, silicon carbonitride, silicon oxycarbonitride, and combinations thereof. However, embodiments of the present disclosure are not necessarily limited thereto. In an embodiment, the gate capping pattern 150 may include a silicon nitride film.

The source/drain pattern 160 may be formed on at least one side surface (e.g., both opposing side surfaces) of the gate structure GS. Further, the source/drain pattern 160 may be connected to the active pattern AP. For example, the upper surface of the buffer layer 112 may be connected to (e.g., directly connected to) the source/drain pattern 160. Further, each of the first to third channel patterns 114, 116, and 118 may extend through the gate structure GS so as to be connected to the source/drain pattern 160. The source/drain pattern 160 may be electrically insulated from the gate electrode 130 via the gate dielectric film 120 and/or the gate spacer 140. In an embodiment, the source/drain pattern 160 may act as a source/drain area of a field effect transistor including the active pattern AP and the gate structure GS.

In some embodiments, the source/drain pattern 160 may include an epitaxial layer. For example, in an embodiment the source/drain pattern 160 may be formed using an epitaxial growth process. As shown in FIG. 5, a cross section of the source/drain pattern 160 intersecting the first direction X may have a pentagon shape. However, embodiments of the present disclosure are not necessarily limited thereto. Depending on an epitaxial growth condition, the cross section of the source/drain pattern 160 intersecting the first direction X may have various shapes, such as a hexagon shape or a diamond shape.

In some embodiments, a height of the bottommost surface of the source/drain pattern 160 may be lower than that of the uppermost surface of the buffer layer 112. For example, a portion of the buffer layer 112 may be recessed, and a lower portion of the source/drain pattern 160 may fill the recessed area of the buffer layer 112. However, embodiments of the present disclosure are not necessarily limited thereto.

In an embodiment in which the field effect transistor including the active pattern AP and the gate structure GS is an NFET, the source/drain pattern 160 may contain n-type impurities or impurities for preventing diffusion of the n-type impurities. For example, the source/drain pattern 160 may contain at least one compound selected from P, Sb, As, and combinations thereof.

In some embodiments, the source/drain pattern 160 may include a tensile stress material. In an embodiment in which the active pattern AP is a silicon (Si) pattern, the source/drain pattern 160 may include a material (e.g., silicon carbide (SiC)) having a smaller lattice constant than that of silicon (Si). The tensile stress material may apply tensile stress to the active pattern AP to increase carrier mobility in the channel area.

In an embodiment in which the field effect transistor including the active pattern AP and the gate structure GS is a PFET, the source/drain pattern 160 may contain p-type impurities or impurities for preventing diffusion of the p-type impurities. For example, the source/drain pattern 160 may contain at least one compound selected from B, C, In, Ga, Al, and combinations thereof.

In some embodiments, the source/drain pattern 160 may include a compressive stress material. In an embodiment in which the active pattern AP is a silicon pattern, the source/drain pattern 160 may include a material (e.g., silicon germanium (SiGe)) having a lattice constant larger than that of silicon (Si). The compressive stress material may apply compressive stress to the active pattern AP to increase carrier mobility in the channel area.

In some embodiments, an inner spacer 145 may be further formed on a side surface of the gate electrode 130. The inner spacer 145 may be formed on the side surface of the gate electrode 130 and between adjacent channel patterns (e.g., adjacent ones of the first to third channel patterns 114, 116, and 118). The gate electrode 130 formed between adjacent channel patterns (e.g., adjacent ones of the first to third channel patterns 114, 116, and 118) may be electrically insulated from the source/drain pattern 160 via the gate dielectric film 120 and the inner spacer 145. However, embodiments of the present disclosure are not necessarily limited thereto. For example, in some embodiments, the inner spacer 145 may be omitted.

In an embodiment, the inner spacer 145 may include, for example, at least one compound selected from silicon nitride, silicon oxynitride, silicon oxycarbide, silicon boron nitride, silicon carbonitride, silicon oxycarbonitride, and combinations thereof. However, embodiments of the present disclosure are not necessarily limited thereto. In an embodiment, the inner spacer 145 may include a silicon nitride film. The inner spacer 145 may include the same material as that of the gate spacer 140 or a material different from that of the gate spacer 140. In an embodiment of FIG. 2, a thickness of the inner spacer 145 is shown to be the same as that of the gate spacer 140. However, embodiments of the present disclosure are not necessarily limited thereto.

In some embodiments, the source/drain pattern 160 may include a first epitaxial layer 162 and a second epitaxial layer 164. The first epitaxial layer 162 may be formed on the active pattern AP. For example, the first epitaxial layer 162 may extend along the upper surface of the buffer layer 112, a side surface of the inner spacer 145, and a side surface of each of the first to third channel patterns 114, 116, and 118. The second epitaxial layer 164 may be stacked on the first epitaxial layer 162. In an embodiment the first epitaxial layer 162 may serve as a seed layer for growing the second epitaxial layer 164.

The first epitaxial layer 162 and the second epitaxial layer 164 may contain impurities at different concentrations. For example, in an embodiment the first epitaxial layer 162 and the second epitaxial layer 164 may contain germanium (Ge) as the compressive stress material at different concentrations. In an embodiment in which a field effect transistor including the active pattern AP and the gate structure GS is a PFET, the germanium concentration of the second epitaxial layer 164 may be greater than that of the first epitaxial layer 162.

The first interlayer insulating film 170 may be formed to fill a space on an outer side surface of the gate spacer 140. For example, the first interlayer insulating film 170 may cover the field insulating film 105 and the source/drain pattern 160.

The second interlayer insulating film 210 may be formed on the first interlayer insulating film 170 (e.g., formed directly thereon in the third direction Z). For example, the second interlayer insulating film 210 may cover an upper surface of the first interlayer insulating film 170, the upper surface of the gate spacer 140, and the upper surface of the gate capping pattern 150.

In an embodiment, each of the first interlayer insulating film 170 and the second interlayer insulating film 210 may include, for example, at least one compound selected from silicon oxide, silicon nitride, silicon oxynitride, silicon oxycarbide, silicon boron nitride, silicon carbonitride, silicon oxycarbonitride and a low dielectric constant material having a dielectric constant than that of silicon oxide. The low dielectric constant material may include, for example, at least one compound selected from FOX (Flowable Oxide), TOSZ (Torene SilaZene), USG (Undoped Silica Glass), BSG (Borosilica Glass), PSG (PhosphoSilica Glass), BPSG (BoroPhosphoSilica Glass), PETEOS (Plasma Enhanced Tetra Ethyl Ortho Silicate), FSG (Fluoride Silicate Glass), CDO (Carbon Doped silicon Oxide), Xerogel, Aerogel, Amorphous Fluorinated Carbon, OSG (Organo Silicate Glass), Parylene, BCB (bis-benzocyclobutenes), SiLK, polyimide, a porous polymeric material, and combinations thereof. However, embodiments of the present disclosure are not necessarily limited thereto.

The upper source/drain contact 180 may extend in the third direction Z and be connected to an upper portion of the source/drain pattern 160. For example, in an embodiment the upper source/drain contact 180 may sequentially extend (e.g., in the third direction Z) through the second interlayer insulating film 210 and the first interlayer insulating film 170 so as to directly contact the source/drain pattern 160.

In an embodiment, a width of the upper source/drain contact 180 may decrease as the upper source/drain contact 180 gets closer to the source/drain pattern 160. In this regard, the width means a width in a plane (e.g., an XY plane) intersecting the third direction Z. The decreasing width may be a result of an etching process for forming the upper source/drain contact 180 that is performed on an upper surface of the source/drain pattern 160.

In some embodiments, the upper source/drain contact 180 may include a first silicide film 182 and a first metal film 184 sequentially stacked on the source/drain pattern 160.

In an embodiment, the first metal film 184 may include a conductive material, for example, a metal material such as cobalt (Co), titanium (Ti), tantalum (Ta), ruthenium (Ru), tungsten (W), or cobalt tungsten phosphorus (CoWP). However, embodiments of the present disclosure are not necessarily limited thereto. In an embodiment, the first metal film 184 may include a cobalt film.

The first silicide film 182 may be interposed between the source/drain pattern 160 and the first metal film 184 (e.g., in the third direction Z). In an embodiment, the first silicide film 182 may be formed by reacting an element included in the first metal film 184 with the source/drain pattern 160. In an embodiment, the first silicide film 182 may include, for example, metal silicide such as nickel silicide, cobalt silicide, tungsten silicide, titanium silicide, niobium silicide, or tantalum silicide. However, embodiments of the present disclosure are not necessarily limited thereto. In an embodiment, the first silicide film 182 may include a titanium silicide film.

The frontside wiring structure FS may be disposed on the second surface 110b of the first base layer 110. For example, the frontside wiring structure FS may be formed on (e.g., formed directly thereon in the third direction Z) an upper surface of the second interlayer insulating film 210.

The frontside wiring structure FS may include a frontside inter-wiring insulating film 310, a plurality of frontside wiring patterns FM1 to FM3, and a plurality of frontside via patterns FV1 to FV3. The frontside wiring patterns FM1 to FM3 may be sequentially stacked on the second surface 110b of the first base layer 110. The frontside via patterns FV1 to FV3 may be sequentially stacked on the second surface 110b of the first base layer 110. The frontside via patterns FV1 to FV3 may connect the frontside wiring patterns FM1 to FM3 to each other. The frontside wiring patterns FM1 to FM3 and the frontside via patterns FV1 to FV3 may be formed in the frontside inter-wiring insulating film 310. The frontside wiring patterns FM1 to FM3 may be insulated from each other via the frontside inter-wiring insulating film 310. The frontside via patterns FV1 to FV3 may be insulated from each other via the frontside inter-wiring insulating film 310. The number of layers, the number and the arrangement of the frontside inter-wiring insulating film 310, the frontside wiring patterns FM1 to FM3 and the frontside via patterns FV1 to FV3 shown in an embodiment of FIG. 2 are merely examples and embodiments of the present disclosure are not necessarily limited thereto.

In some embodiments, a width of each of the frontside via patterns FV1 to FV3 may decrease as each of the frontside via patterns FV1 to FV3 gets closer to the second surface 110b of the first base layer 110. The decreasing width of the frontside via patterns FV1 to FV3 may be a result of the characteristics of an etching process for forming the frontside via patterns FV1 to FV3.

In an embodiment, the frontside wiring structure FS may act as a signal line and/or a power line for a variety of electronic elements (e.g., a field effect transistor including the active pattern AP and the gate structure GS) formed on the second surface 110b of the first base layer 110. For example, the first frontside via pattern FV1 of the frontside wiring structure FS may be connected to (e.g., directly connected thereto) the upper source/drain contact 180. Thus, the frontside wiring structure FS may be electrically connected to the source/drain pattern 160.

In some embodiments, the gate contact 185 may be formed on the gate structure GS (e.g., formed directly thereon in the third direction Z). The gate contact 185 may sequentially extend through the second interlayer insulating film 210, the first interlayer insulating film 170, and the gate capping pattern 150 so as to be connected to the gate electrode 130. The gate contact 185 may connect the gate electrode 130 and the first frontside wiring pattern FM1 to each other. Thus, the frontside wiring structure FS may be electrically connected to the gate electrode 130. However, embodiments of the present disclosure are not necessarily limited thereto. For example, in some embodiments, the gate contact 185 may connect the gate electrode 130 and the first frontside via pattern FV1 to each other.

In an embodiment, each of the frontside wiring patterns FM1 to FM3 and the frontside via patterns FV1 to FV3 may include a barrier conductive film and a filling conductive film. The barrier conductive film may include a metal or a metal nitride to prevent diffusion of the filling conductive film. In an embodiment, the barrier conductive film may include, for example, at least one compound selected from titanium (Ti), tantalum (Ta), tungsten (W), nickel (Ni), cobalt (Co), platinum (Pt), alloys thereof, and nitrides thereof. However, embodiments of the present disclosure are not necessarily limited thereto. The filling conductive film may include, for example, at least one compound selected from aluminum (Al), copper (Cu), tungsten (W), molybdenum (Mo), cobalt (Co), ruthenium (Ru), and alloys thereof. However, embodiments of the present disclosure are not necessarily limited thereto.

The lower source/drain contact 190 may extend in the third direction Z so as to be connected to (e.g., directly connected to) a lower portion of the source/drain pattern 160. For example, the lower source/drain contact 190 may sequentially extend through the first base layer 110 and the buffer layer 112 so as to directly contact the source/drain pattern 160.

In an embodiment, a width of the lower source/drain contact 190 may decrease as the lower source/drain contact 190 extends toward the source/drain pattern 160. In this regard, the width means a width in the plane (e.g., the XY plane) intersecting the third direction Z. The decreasing width may be a result of an etching process for forming the lower source/drain contact 190 that is performed on a lower surface of the source/drain pattern 160.

In some embodiments, the lower source/drain contact 190 may include a second silicide film 192 and a second metal film 194 sequentially stacked on the source/drain pattern 160 (e.g., in the third direction Z).

In an embodiment, the second metal film 194 may include a conductive material, for example, a metal material such as cobalt (Co), titanium (Ti), tantalum (Ta), ruthenium (Ru), tungsten (W), or cobalt tungsten phosphorus (CoWP). However, embodiments of the present disclosure are not necessarily limited thereto. In an embodiment, the second metal film 194 may include a cobalt film.

The second silicide film 192 may be interposed between the source/drain pattern 160 and the second metal film 194 (e.g., in the third direction Z). The second silicide film 192 may be formed by reacting an element included in the second metal film 194 with the source/drain pattern 160. In an embodiment, the second silicide film 192 may include, for example, metal silicide such as nickel silicide, cobalt silicide, tungsten silicide, titanium silicide, niobium silicide, or tantalum silicide. However, embodiments of the present disclosure are not necessarily limited thereto. In an embodiment, the second silicide film 192 may include a titanium silicide film.

In an embodiment as shown in FIG. 3, the lower source/drain contact 190 may include a first side surface 190s1 disposed in the first base layer 110 and a second side surface 190s2 disposed in the buffer layer 112. In some embodiments, a first inclination angle θ1 of the first side surface 190s1 and a second inclination angle θ2 of the second side surface 190s2 may be different from each other. For example, in an embodiment as shown in FIG. 3, the second inclination angle θ2 of the second side surface 190s2 may be less than the first inclination angle θ1 of the first side surface 190s1. The first and second inclination angles θ1, θ2 may be measured from the second surface 110b of the base layer 110 extending in the first direction X. The difference in the first and second inclination angles θ1, θ2 may be a result of characteristics of an etching process for forming the lower source/drain contact 190.

The backside wiring structure BS may be disposed on the first surface 110a of the first base layer 110 (e.g., disposed directly thereon in the third direction Z). For example, the backside wiring structure BS may be formed on (e.g., formed directly thereon) the lower surface of the first base layer 110.

The backside wiring structure BS may include a backside inter-wiring insulating film 320, a plurality of backside wiring patterns BM1 and BM2, and a plurality of backside via patterns BV1 and BV2. The backside wiring patterns BM1 and BM2 may be sequentially stacked on the first surface 110a of the first base layer 110. The backside via patterns BV1 and BV2 may be sequentially stacked on the first surface 110a of the first base layer 110. The backside via patterns BV1 and BV2 may connect the backside wiring patterns BM1 and BM2 to each other. The backside wiring patterns BM1 and BM2 and the backside via patterns BV1 and BV2 may be formed in the backside inter-wiring insulating film 320. The backside wiring patterns BM1 and BM2 may be insulated from each other via the backside inter-wiring insulating film 320. The backside via patterns BV1 and BV2 may be insulated from each other via the backside inter-wiring insulating film 320. The number of layers, the number and the arrangement of the backside inter-wiring insulating film 320, the backside wiring patterns BM1 and BM2 and the backside via patterns BV1 and BV2 are merely examples and embodiments of the present disclosure are not necessarily limited thereto.

In some embodiments, a width of each of the backside via patterns BV1 and BV2 may decrease as each of the backside via patterns BV1 and BV2 gets closer to the first surface 110a of the first base layer 110. The decreasing width of the backside via patterns BV1 and BV2 may be a result of characteristics of an etching process for forming the backside via patterns BV1 and BV2.

In some embodiments, the backside wiring structure BS may include a power rail PR. The power rail PR may extend along the first surface 110a of the first base layer 110 so as to be connected to (e.g., directly connected to) the lower source/drain contact 190. Further, the first backside via pattern BV1 may be connected to the power rail PR, such as a lower surface of the power rail PR. In some embodiments, a plurality of power rails PR may extend in a parallel manner to each other in the first direction X and may be spaced apart from each other in the second direction Y.

In some embodiments, the backside wiring structure BS may act as a power delivery network (PDN) for various electronic elements (e.g., a field effect transistor including the active pattern AP and the gate structure GS) formed on the second surface 110b of the first base layer 110. For example, in an embodiment a power voltage (e.g., a source voltage V_{SS} or a drain voltage V_{DD}) supplied from an external source may be transferred to the uppermost wiring (e.g., the second backside wiring pattern BM2) of the backside wiring structure BS, and then may be transmitted to the source/drain pattern 160 via the power rail PR and the lower source/drain contact 190.

In an embodiment, each of the backside wiring patterns BM1 and BM2 and the backside via patterns BV and BV2 may include a barrier conductive film and a filling conductive film. The barrier conductive film may include a metal or a metal nitride to prevent diffusion of the filling conductive film. In an embodiment, the barrier conductive film may include, for example, at least one compound selected from titanium (Ti), tantalum (Ta), tungsten (W), nickel (Ni), cobalt (Co), platinum (Pt), alloys thereof, and nitrides thereof. However, embodiments of the present disclosure are not necessarily limited thereto. In an embodiment, the filling conductive film may include, for example, at least one compound selected from aluminum (Al), copper (Cu), tungsten (W), molybdenum (Mo), cobalt (Co), ruthenium (Ru), and alloys thereof. However, embodiments of the present disclosure are not necessarily limited thereto.

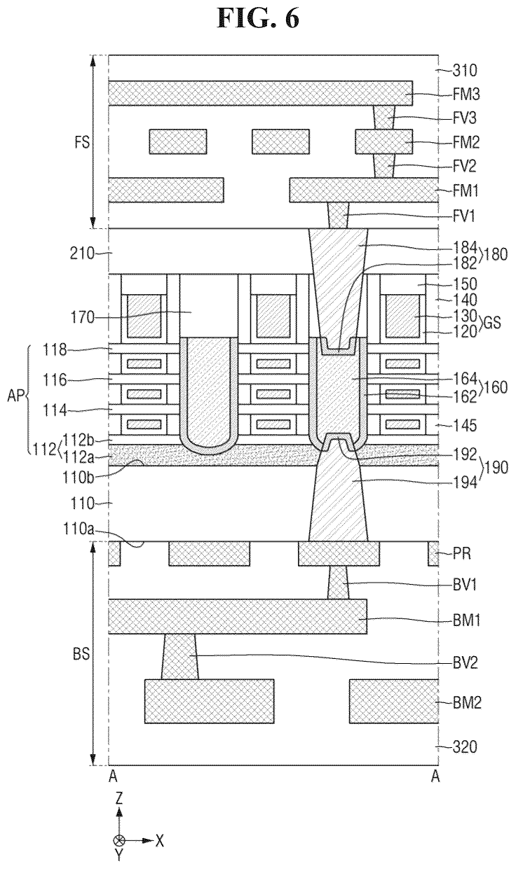

FIGS. 6 to 9 are various cross-sectional views for illustrating semiconductor devices according to some embodiments, respectively. For convenience of descriptions, descriptions duplicate with those as set forth above with reference to FIGS. 1 to 5 may be briefly set forth or omitted. For reference, FIGS. 6 to 9 are different schematic cross-sections taken along A-A of FIG. 1, respectively.

Referring to FIG. 6, in a semiconductor device according to some embodiments, the buffer layer 112 includes a first semiconductor layer 112a and a second semiconductor layer 112b.

The first semiconductor layer 112a and the second semiconductor layer 112b may be sequentially stacked on the second surface 110b of the first base layer 110 (e.g., in the third direction Z). The first semiconductor layer 112a and the second semiconductor layer 112b may include different semiconductor materials from each other. For example, in an embodiment the first semiconductor layer 112a may include a silicon germanium (SiGe) layer, and the second semiconductor layer 112b may include a silicon (Si) layer. However, embodiments of the present disclosure are not necessarily limited thereto.

In some embodiments, each of the first semiconductor layer 112a and the second semiconductor layer 112b may further contain high-concentration impurities to prevent a punch through phenomenon. In an embodiment in which a field effect transistor including the active pattern AP and the gate structure GS is an NFET, each of the first semiconductor layer 112a and the second semiconductor layer 112b may contain p-type impurities at a high concentration. In an embodiment in which a field effect transistor including the active pattern AP and the gate structure GS is a PFET, each of the first semiconductor layer 112a and the second semiconductor layer 112b may contain n-type impurities at a high concentration.

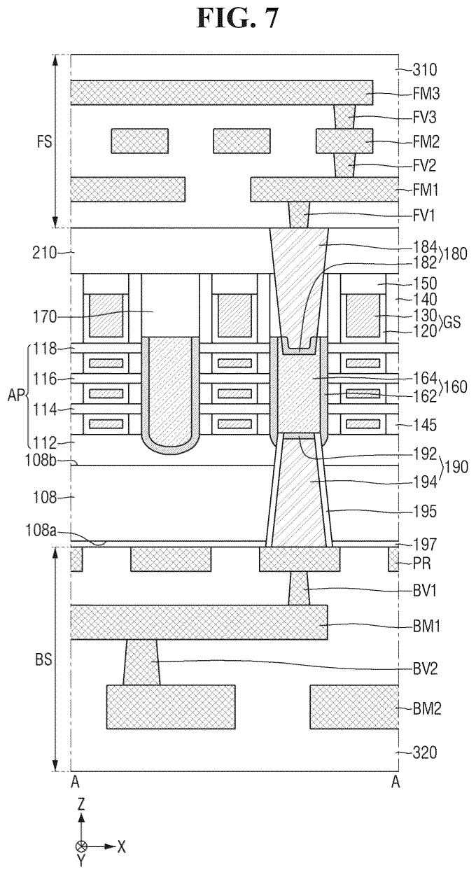

Referring to FIG. 7, a semiconductor device according to some embodiments includes a second base layer 108.

In an embodiment, the second base layer 108 may include a semiconductor material. For example, in an embodiment the second base layer 108 may be a silicon (Si) layer, or may include a material other than silicon, such as silicon germanium, silicon germanium on insulator (SGOI), indium antimonide, a lead telluride compound, indium arsenide, indium phosphide, gallium arsenide or gallium antimonide. However, embodiments of the present disclosure are not necessarily limited thereto.

The second base layer 108 may include a third surface 108a and a fourth surface 108b that are opposite to each other (e.g., in the third direction Z). For example, as shown in an embodiment of FIG. 7, the third surface 108a may be a lower surface of the second base layer 108 and the fourth surface 108b may be an upper surface of the second base layer 108. As used herein, the third surface 108a may also be referred to as a backside of the second base layer 108, and the fourth surface 108b may be referred to as a frontside of the second base layer 108.

The second base layer 108 may replace the first base layer 110 as described above with reference to embodiments of FIGS. 2 to 5. For example, in an embodiment the active pattern AP, the field insulating film 105, the gate structure GS, the gate spacer 140, the gate capping pattern 150, the source/drain pattern 160, the first interlayer insulating film 170, the second interlayer insulating film 210, the upper source/drain contact 180, and the frontside wiring structure FS may be disposed on the fourth surface 108b of the second base layer 108. Further, the lower source/drain contact 190 and the backside wiring structure BS may be disposed on the third surface 108a of the second base layer 108.

In some embodiments, a contact spacer 195 may be formed on a side surface of the lower source/drain contact 190. The contact spacer 195 may extend along a side surface of the lower source/drain contact 190. The contact spacer 195 may electrically insulate the lower source/drain contact 190 and the second base layer 108 from each other and may electrically insulate the lower source/drain contact 190 and the buffer layer 112 from each other. In an embodiment, the contact spacer 195 may include an insulating material, for example, at least one compound selected from silicon oxide, silicon nitride, silicon oxynitride, and combinations thereof. However, embodiments of the present disclosure are not necessarily limited thereto.

In some embodiments, an isolation insulating film 197 may be formed on the third surface 108a of the second base layer 108 (e.g., formed directly thereon in the third direction Z). The isolation insulating film 197 may extend along the third surface 108a of the second base layer 108. The isolation insulating film 197 may electrically insulate the second base layer 108 from the backside wiring structure BS (e.g., the power rail PR). In an embodiment, the isolation insulating film 197 may include an insulating material, for example, at least one material selected from silicon oxide, silicon nitride, silicon oxynitride, and combinations thereof. However, embodiments of the present disclosure are not necessarily limited thereto.

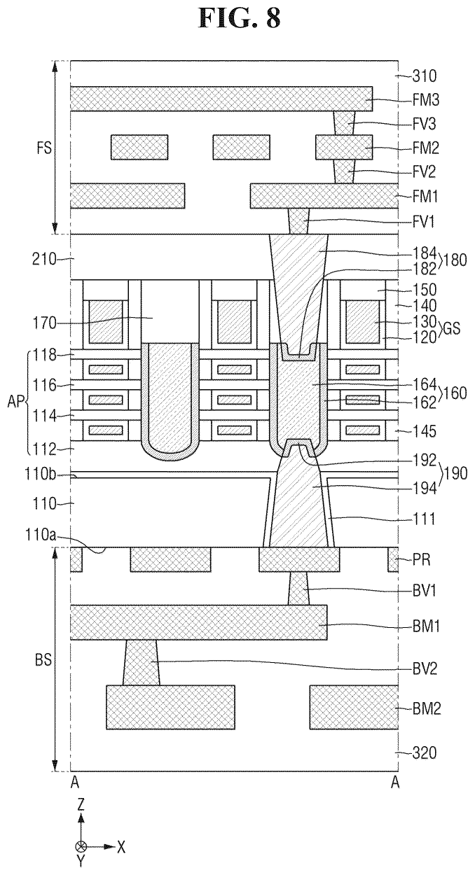

Referring to FIG. 8, a semiconductor device according to some embodiments further includes a liner film 111.

The liner film 111 may extend along the lower surface of the buffer layer 112 and the side surface of the lower source/drain contact 190. The first base layer 110 may be stacked on the liner film 111 (e.g., stacked directly thereon in the third direction Z). For example, the second surface 110b of the first base layer 110 may face the liner film 111. In an embodiment, the liner film 111 may include an insulating material, for example, at least one material selected from silicon oxide, silicon nitride, silicon oxynitride, and combinations thereof. However, embodiments of the present disclosure are not necessarily limited thereto. In an embodiment, the liner film 111 may include a silicon nitride film.

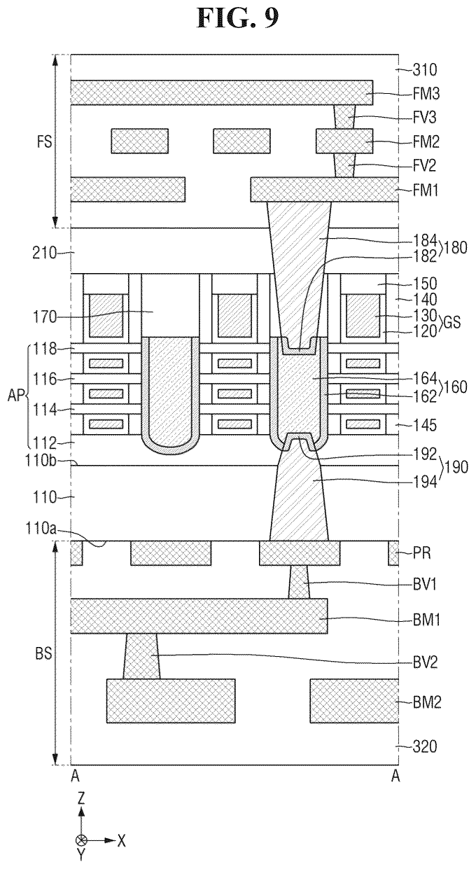

Referring to FIG. 9, in the semiconductor device according to some embodiments, the upper source/drain contact 180 directly contacts the first frontside wiring pattern FM1.

For example, the first frontside via pattern FV1 as described above with reference to embodiments of FIGS. 2 to 5 may be omitted. Thus, the frontside wiring structure FS may be electrically connected to the source/drain pattern 160.

Hereinafter, referring to FIGS. 1 to 35, a method for manufacturing a semiconductor device according to some embodiments is described.

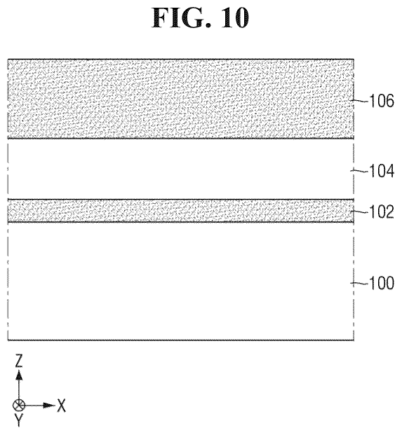

FIGS. 10 to 29 are diagrams of intermediate structures corresponding to intermediate steps for illustrating a method for manufacturing a semiconductor device according to some embodiments. For convenience of description, descriptions duplicate with those as set forth above with reference to FIGS. 1 to 9 are briefly set forth or omitted.

Referring to FIG. 10, an etch stop film 102, a buffer substrate 104, and a sacrificial contact film 106 are sequentially formed on a base substrate 100 (e.g., in the third direction Z). For example, the method may include a step of providing a buffer substrate 104.

In an embodiment, the base substrate 100 may be made of bulk silicon or silicon-on-insulator (SOI). Alternatively, the base substrate 100 may be a silicon substrate, or may include a material other than silicon, such as silicon germanium, silicon germanium on insulator (SGOI), indium antimonide, a lead telluride compound, indium arsenide, indium phosphide, gallium arsenide or gallium antimonide. However, embodiments of the present disclosure are not necessarily limited thereto. For convenience of description, an example in which the base substrate 100 is embodied as the silicon substrate is described below.

The etch stop film 102 may be deposited on the base substrate 100 (e.g., deposited directly thereon). In an embodiment, the etch stop film 102 may have an etch selectivity different from that of the base substrate 100. In an embodiment in which the base substrate 100 is a silicon substrate, the etch stop film 102 may include a silicon germanium (SiGe) layer. In some embodiments, the etch stop film 102 may be formed by performing an epitaxial growth process using the base substrate 100 as a seed layer.

The buffer substrate 104 may be deposited on the etch stop film 102 (e.g., deposited directly thereon). The buffer substrate 104 may have an etch selectivity different from that of the etch stop film 102. In an embodiment in which the etch stop film 102 is a silicon germanium (SiGe) layer, the buffer substrate 104 may include a silicon (Si) layer. In some embodiments, the buffer substrate 104 may be formed by performing an epitaxial growth process using the etch stop film 102 as a seed layer.

The sacrificial contact film 106 may be deposited on the buffer substrate 104 (e.g., deposited directly thereon). In an embodiment, the sacrificial contact film 106 may have an etching selectivity different from that of the buffer substrate 104. For example, in an embodiment in which the buffer substrate 104 includes a silicon (Si) layer, the sacrificial contact film 106 may include a silicon germanium (SiGe) layer. In some embodiments, the sacrificial contact film 106 may be formed by performing an epitaxial growth process using the buffer substrate 104 as a seed layer.

In some embodiments, the sacrificial contact film 106 may further contain impurities. The impurities may reduce stress due to a difference between lattice constants of the buffer substrate 104 and the sacrificial contact film 106. For example, in an embodiment in which the buffer substrate 104 includes a silicon (Si) layer and the sacrificial contact film 106 includes a silicon germanium (SiGe) layer, the impurities may include at least one compound selected from carbon (C), boron (B), arsenic (As), phosphorus (P), antimony (Sb), gallium (Ga), and tin (Sn).

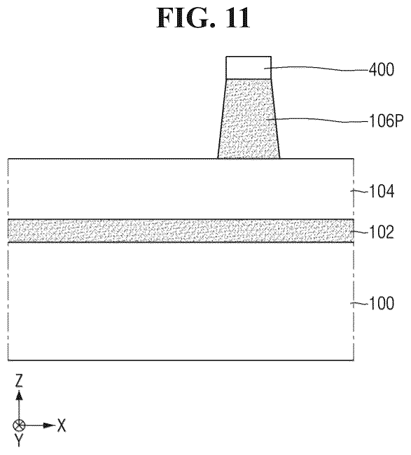

Referring to FIGS. 10 and 11, the sacrificial contact film 106 is then patterned to form a sacrificial contact pattern 106P.

For example, in an embodiment, a first mask pattern 400 may be formed on the sacrificial contact film 106 (e.g., formed directly thereon in the third direction Z). Subsequently, an etching process may be performed on the sacrificial contact film 106 using the first mask pattern 400 as an etch mask After the etching process is performed, a portion of an upper surface of the buffer substrate 104 may be exposed. As described above, since the sacrificial contact film 106 may have the etching selectivity different from that of the buffer substrate 104, the sacrificial contact film 106 may be selectively etched. Thus, the sacrificial contact pattern 106P may be formed on the buffer substrate 104.

In some embodiments, a width of the sacrificial contact pattern 106P may increase as the sacrificial contact pattern 106P gets closer to the buffer substrate 104. In this regard, the width means a width in the plane (e.g., the XY plane) intersecting the third direction Z. The decreasing width of the sacrificial contact pattern 106P may be a result of an etching process for forming the sacrificial contact pattern 106P that is performed on an upper surface of the sacrificial contact film 106.

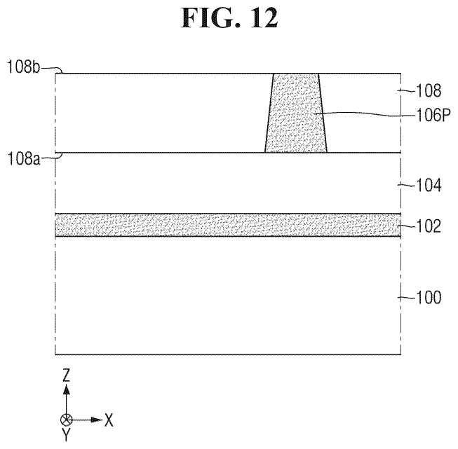

Referring to FIG. 12, the second base layer 108 is formed on (e.g., formed directly thereon) the buffer substrate 104 and the sacrificial contact pattern 106P.

The second base layer 108 may surround the sacrificial contact pattern 106P. For example, the second base layer 108 may cover an upper surface of the buffer substrate 104 and a side surface (e.g., lateral side surfaces) of the sacrificial contact pattern 106P. In an embodiment, the second base layer 108 may have an etch selectivity different from that of the sacrificial contact pattern 106P. For example, in an embodiment in which the sacrificial contact pattern 106P includes a silicon germanium (SiGe) layer, the second base layer 108 may include a silicon (Si) layer.

The second base layer 108 may include the third surface 108a and the fourth surface 108b that are opposite to each other. For example, as shown in an embodiment of FIG. 12, the third surface 108a may be a lower surface of the second base layer 108 and the fourth surface 108b may be an upper surface of the second base layer 108. As described above, since the width of the sacrificial contact pattern 106P may increase as the sacrificial contact pattern 106P gets closer to the buffer substrate 104, the width of the sacrificial contact pattern 106P may increase as the sacrificial contact pattern 106P extends in a direction from the fourth surface 108b to the third surface 108a.

In some embodiments, the second base layer 108 may be formed by performing an epitaxial growth process using the buffer substrate 104 and the sacrificial contact pattern 106P as a seed layer. For example, the epitaxial growth process may be performed to form an epitaxial layer covering the buffer substrate 104 and the sacrificial contact pattern 106P. Subsequently, a planarization process may be performed on the epitaxial layer to expose an upper surface of the sacrificial contact pattern 106P. Thus, the second base layer 108 surrounding the side surface of the sacrificial contact pattern 106P may be formed. In some embodiments, the first mask pattern 400 may be removed using the planarization process.

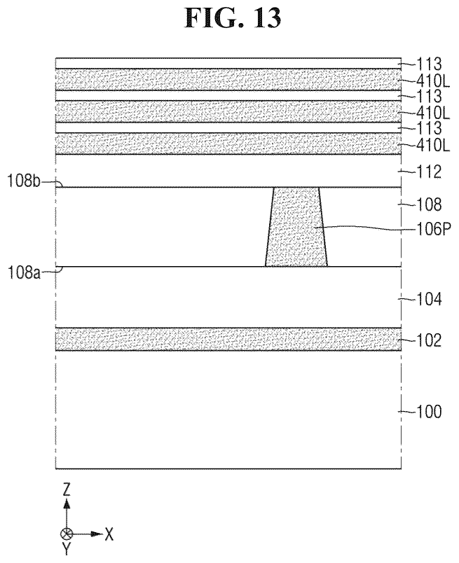

Referring to FIG. 13, the buffer layer 112, a plurality of sacrificial layers 410L, and a plurality of active layers 113 are formed on the second base layer 108 and the sacrificial contact pattern 106P.

In an embodiment, the buffer layer 112 may be deposited on (e.g., deposited directly thereon the second base layer 108 and the sacrificial contact pattern 106P. For example, the buffer layer 112 may extend along the upper surface of the second base layer 108 and the upper surface of the sacrificial contact pattern 106P. In an embodiment, a thickness of the buffer layer 112 may be, for example, in a range of about 1 nm to about 500 nm. In an embodiment, the buffer layer 112 may include an elemental semiconductor material, for example, silicon (Si) or germanium (Ge).

The plurality of sacrificial layers 410L and the plurality of active layers 113 may be alternately stacked on top of each other (e.g., in the third direction Z) while being disposed on the buffer layer 112. In an embodiment, each of the active layers 113 may include an elemental semiconductor material, for example, silicon (Si) or germanium (Ge). However, embodiments of the present disclosure are not necessarily limited thereto. In an embodiment, each of the active layers 113 may include a silicon (Si) layer. The sacrificial layers 410L may have an etch selectivity different from that of the active layers 113. In an embodiment in which each of the active layers 113 includes a silicon (Si) layer, each of the sacrificial layers 410L may include a silicon germanium (SiGe) layer.

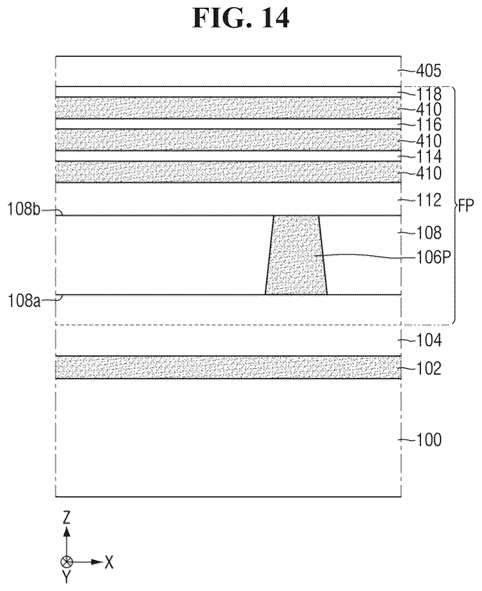

Referring to FIGS. 13 and 14, the sacrificial layers 410L and the active layers 113 are patterned to form a fin pattern FP. For example, in an embodiment a second mask pattern 405 extending in an elongated manner in the first direction X may be formed on the sacrificial layers 410L and the active layers 113. Subsequently, an etching process may be performed on the sacrificial layers 410L and the active layers 113 using the second mask pattern 405 as an etch mask. Accordingly, the fin pattern FP including the first to third channel patterns 114, 116, and 118 extending in the first direction X and a plurality of sacrificial patterns 410 may be formed.

In some embodiments, the fin pattern FP may further include at least a portion of the sacrificial contact pattern 106P, at least a portion of the second base layer 108, and/or at least a portion of the buffer substrate 104. In an embodiment, a portion of the buffer substrate 104 may be etched by an etching process using the second mask pattern 405. In this embodiment, the fin pattern FP may protrude from an upper surface of the buffer substrate 104 so as to extend in the first direction X.

In an embodiment, after the fin pattern FP is formed, the field insulating film (105 in FIG. 4) covering a portion of a side surface of the fin pattern FP may be formed. For example, the field insulating film 105 may cover a side surface (e.g., a lateral side surface) of the buffer substrate 104, a portion of a side surface (e.g., a lateral side surface) of the sacrificial contact pattern 106P, and a portion of a side surface (e.g., a lateral side surface) of the second base layer 108.

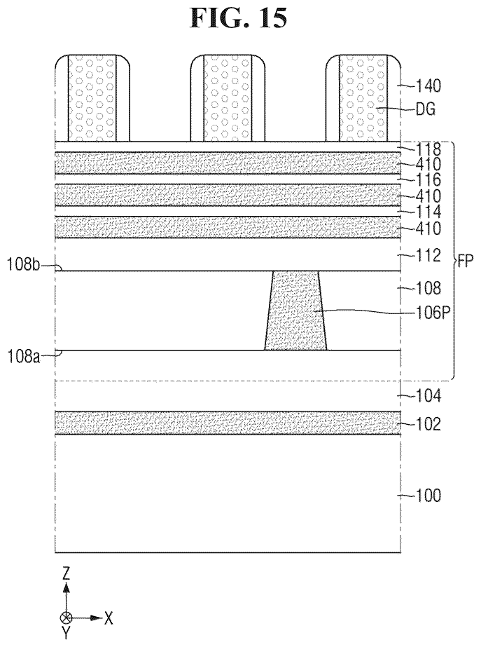

Referring to FIG. 15, a dummy gate DG and the gate spacer 140 are formed on the fin pattern FP (e.g., formed directly thereon in the third direction Z).

The dummy gate DG may be formed on the fin pattern FP and the field insulating film 105. Further, the dummy gate DG may intersect the fin pattern FP. For example, the dummy gate DG may extend in an elongated manner in the second direction Y. In an embodiment, the dummy gate DG may have an etch selectivity that is different from that of each of the first to third channel patterns 114, 116, and 118 and the plurality of sacrificial patterns 410. In an embodiment, the dummy gate DG may include poly silicon (poly Si).

The gate spacer 140 may extend along a side surface (e.g., lateral side surfaces) of the dummy gate DG. This gate spacer 140 may intersect the fin pattern FP. In an embodiment, the gate spacer 140 may include an insulating material, for example, at least one compound selected from silicon nitride, silicon oxynitride, silicon oxycarbide, silicon boron nitride, silicon carbonitride, silicon oxycarbonitride, and combinations thereof. However, embodiments of the present disclosure are not necessarily limited thereto. In an embodiment, the gate spacer 140 may include a silicon nitride film.

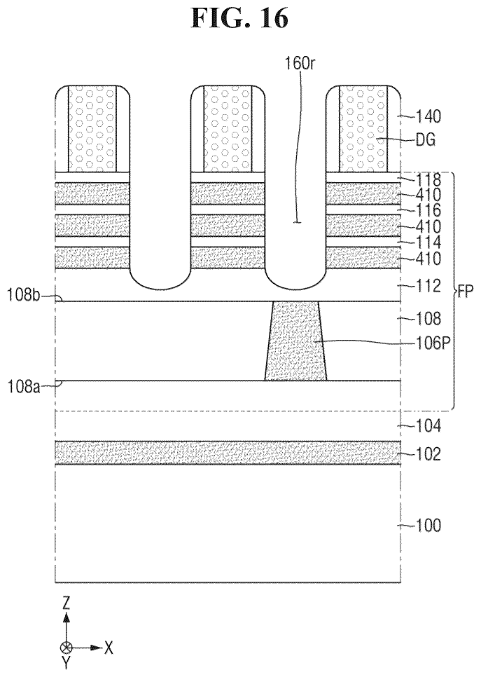

Referring to FIG. 16, a source/drain recess 160r is formed in the fin pattern FP and on a side surface (e.g., a lateral side surface) of the dummy gate DG. For example, in an embodiment a first recess process may be performed on the first to third channel patterns 114, 116, and 118 and the plurality of sacrificial patterns 410 using the dummy gate DG and the gate spacer 140 as an etch mask. As the first recess process is performed, a portion of each of the first to third channel patterns 114, 116, and 118 and a portion of each of the sacrificial patterns 410 may be removed to form the source/drain recess 160r.

The source/drain recess 160r may be disposed above and aligned with the sacrificial contact pattern 106P. For example, the source/drain recess 160r may be formed to overlap the sacrificial contact pattern 106P in the third direction Z.

In some embodiments, a portion of the buffer layer 112 (e.g., an upper portion) may be removed as the first recess process is performed. In this embodiment, a height of the bottommost surface of the source/drain recess 160r may be lower than that of the uppermost surface of the buffer layer 112.

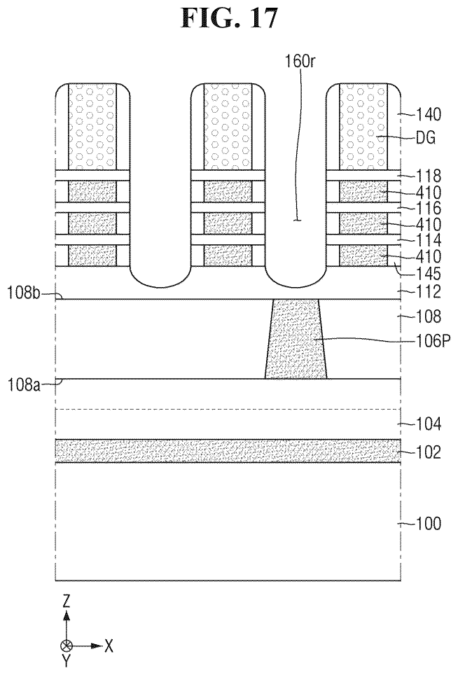

Referring to FIG. 17, in an embodiment the inner spacer 145 is formed on a side surface (e.g., a lateral side surface) of each sacrificial pattern 410.

For example, in an embodiment a second recess process may be performed on side surfaces (e.g., lateral side surfaces) of the sacrificial patterns 410 exposed though the source/drain recess 160r. As the second recess process is performed, the side surface of each of the sacrificial patterns 410 may be recessed. Subsequently, the inner spacers 145 may be formed on the recessed side surface of each of the sacrificial patterns 410. In an embodiment, the inner spacer 145 may include an insulating material, for example, at least one compound selected from silicon nitride, silicon oxynitride, silicon oxycarbide, silicon boron nitride, silicon carbonitride, silicon oxycarbonitride, and combinations thereof. However, embodiments of the present disclosure are not necessarily limited thereto. In an embodiment, the gate spacer 140 may include a silicon nitride film.

However, embodiments of the present disclosure are not necessarily limited thereto. For example, in some embodiments, forming the inner spacer 145 may be omitted.

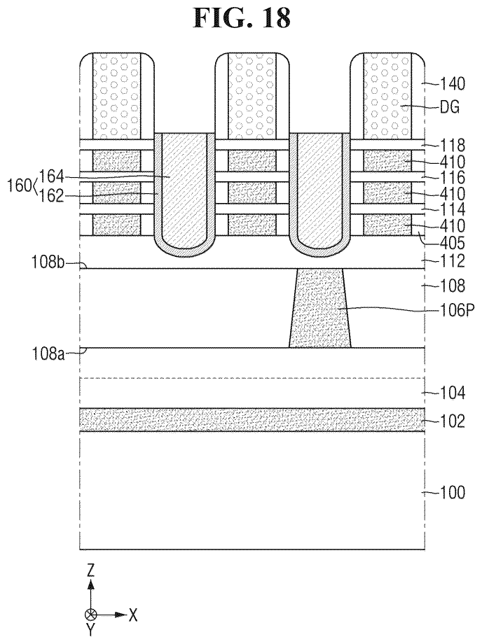

Referring to FIGS. 17 and 18, the source/drain pattern 160 filling the source/drain recess 160r is formed.

For example, in an embodiment an epitaxial growth process may be performed using the buffer layer 112 and the first to third channel patterns 114, 116, and 118 as a seed layer. As a result, the source/drain pattern 160 connected to (e.g., directly connected thereto) the buffer layer 112 and each of the first to third channel patterns 114, 116, and 118 may be formed. Further, the source/drain pattern 160 may overlap with the sacrificial contact pattern 106P in the third direction Z.

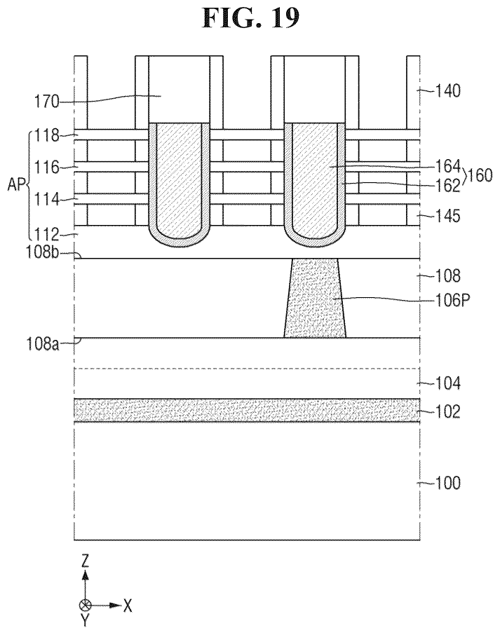

Referring to FIGS. 18 and 19, the sacrificial patterns 410 and the dummy gate DG are removed.

For example, in an embodiment the first interlayer insulating film 170 may be formed on the dummy gate DG, the gate spacer 140, and the source/drain pattern 160. The first interlayer insulating film 170 may be formed to fill a space on an outer side surface of the gate spacer 140. Subsequently, a planarization process may be performed on the first interlayer insulating film 170 to expose an upper surface of the dummy gate DG. Subsequently, the exposed dummy gate DG may be removed. As described above, since the dummy gate DG may have an etch selectivity different from that of each of the first to third channel patterns 114, 116, and 118 and the plurality of sacrificial patterns 410, the dummy gate DG may be selectively removed. As the dummy gate DG has been removed, the plurality of sacrificial patterns 410 may be exposed.

Subsequently, the exposed plurality of sacrificial patterns 410 may be removed. As described above, since the sacrificial patterns 410 may have an etch selectivity different from that of each of the first to third channel patterns 114, 116, and 118, the sacrificial patterns 410 may be selectively removed. As a result, the active pattern AP including the buffer layer 112 and the first to third channel patterns 114, 116, and 118 may be formed as shown in an embodiment of FIG. 19.

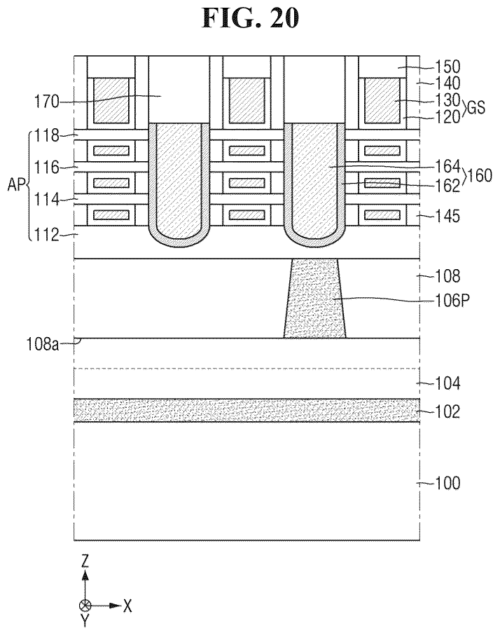

Referring to FIG. 20, the gate structure GS is formed.

For example, in an embodiment the gate dielectric film 120 and the gate electrode 130 may be sequentially stacked on the active pattern AP. Thus, the gate structure GS intersecting the active pattern AP may be formed so as to replace the dummy gate DG.

In some embodiments, an upper portion of the gate structure GS may be recessed. Subsequently, the gate capping pattern 150 may be formed in the recessed upper surface of the gate structure GS. However, embodiments of the present disclosure are not necessarily limited thereto.

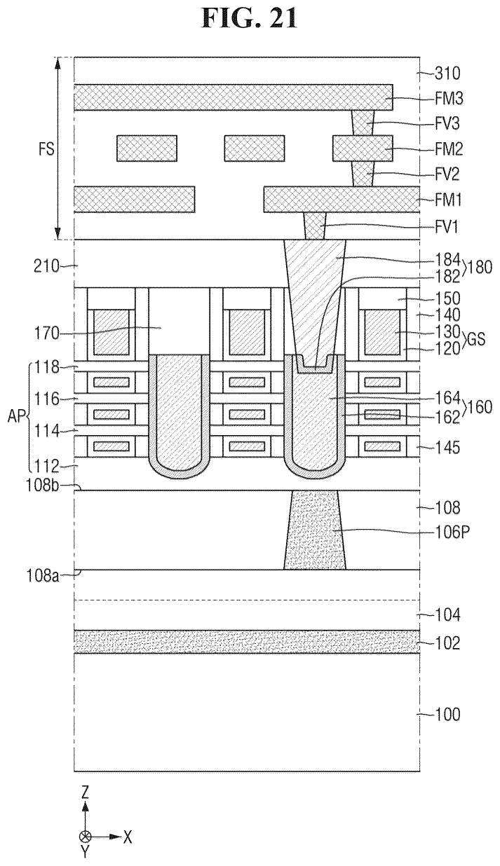

Referring to FIG. 21, the second interlayer insulating film 210, the upper source/drain contact 180, and the frontside wiring structure FS are formed.

For example, in an embodiment the second interlayer insulating film 210 may be formed to cover the upper surface of the first interlayer insulating film 170, the upper surface of the gate spacer 140, and the upper surface of the gate capping pattern 150. Subsequently, the upper source/drain contact 180 extending in the third direction Z so as to sequentially extend through the second interlayer insulating film 210 and the first interlayer insulating film 170 may be formed. The upper source/drain contact 180 may directly contact the source/drain pattern 160.

Subsequently, the frontside wiring structure FS may be formed on (e.g., formed directly thereon in the third direction Z) the upper surface of the second interlayer insulating film 210 and the upper surface of the upper source/drain contact 180. Accordingly, the frontside wiring structure FS may be formed on the fourth surface 108b of the second base layer 108. The frontside wiring structure FS may include the frontside inter-wiring insulating film 310, the plurality of frontside wiring patterns FM1 to FM3, and the plurality of frontside via patterns FV1 to FV3.

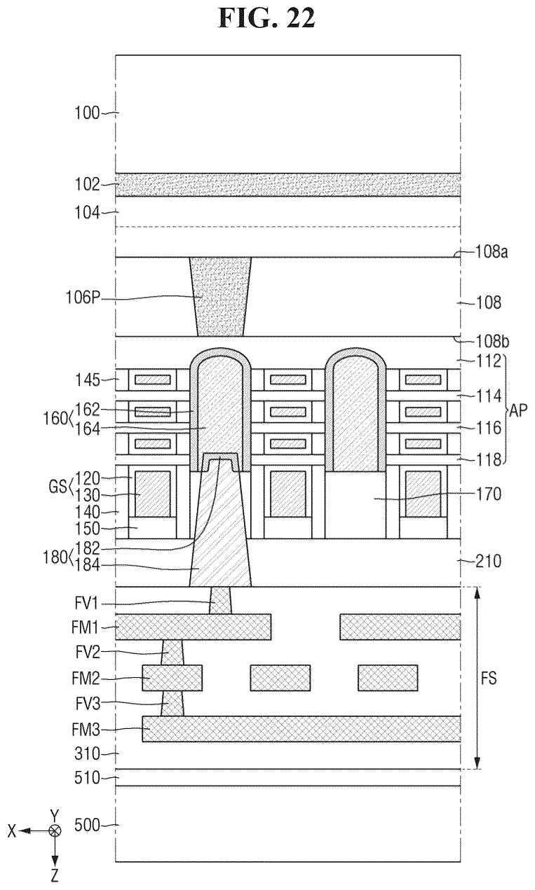

Referring to FIG. 22, in an embodiment the frontside wiring structure FS is attached onto a carrier substrate 500.

For example, the carrier substrate 500 may be attached to a resulting structure shown in FIG. 21. After the carrier substrate 500 has been attached thereto, the resulting structure in FIG. 21 may be turned upside down. For example, the third surface 108a of the second base layer 108 may be inverted to face upwardly.

In some embodiments, the frontside wiring structure FS may be attached onto the carrier substrate 500 via an oxide-oxide bonding process. For example, in an embodiment an oxide layer 510 may be formed on the carrier substrate 500, and the frontside inter-wiring insulating film 310 may be attached to the oxide layer 510 via an oxide-oxide bonding process. However, embodiments of the present disclosure are not necessarily limited thereto.

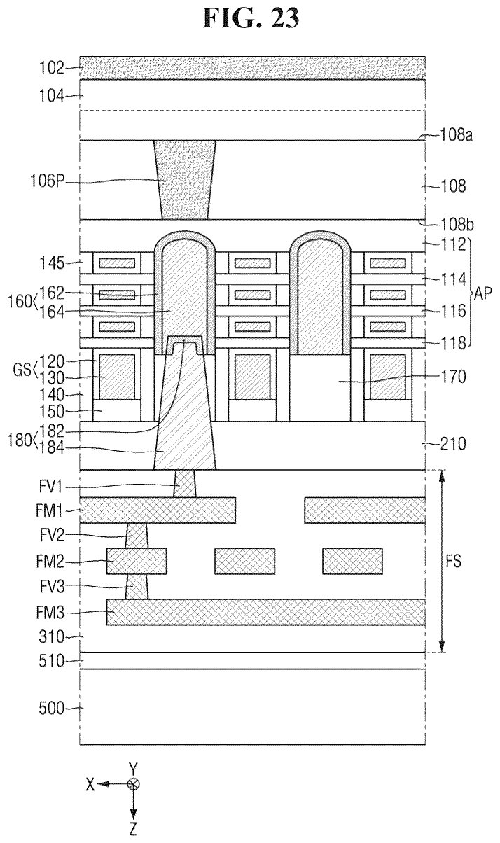

Referring to FIGS. 22 and 23, the base substrate 100 may be removed.

For example, in an embodiment a grinding process and/or a planarization process may be performed on the base substrate 100. The etch stop film 102 may serve as an etch stop film against the grinding process and/or the planarization process.

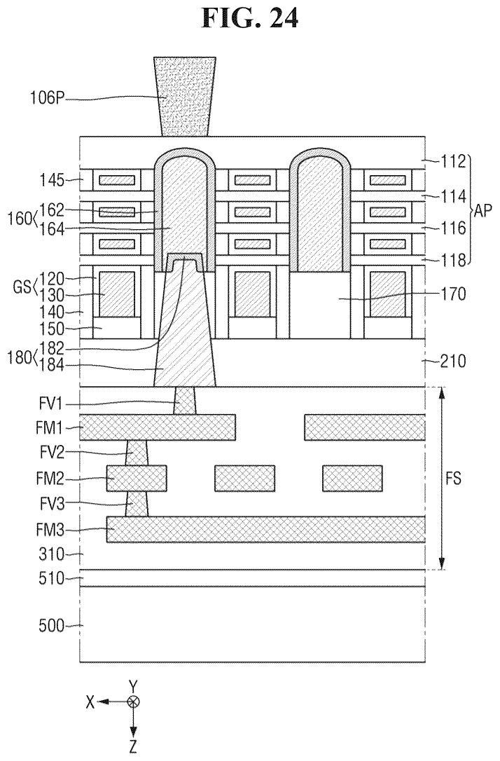

Referring to FIGS. 23 and 24, the sacrificial contact pattern 106P is exposed.

For example, the etch stop film 102 may be removed. Subsequently, the buffer substrate 104 and the second base layer 108 may be removed. As described above, since each of the buffer substrate 104 and the second base layer 108 may have an etching selectivity different from that of the sacrificial contact pattern 106P, the buffer substrate 104 and the second base layer 108 may be selectively removed. As a result, an upper surface and a side surface (e.g., lateral side surfaces) of the sacrificial contact pattern 106P may be exposed. Further, an upper surface of the buffer layer 112 may be exposed.

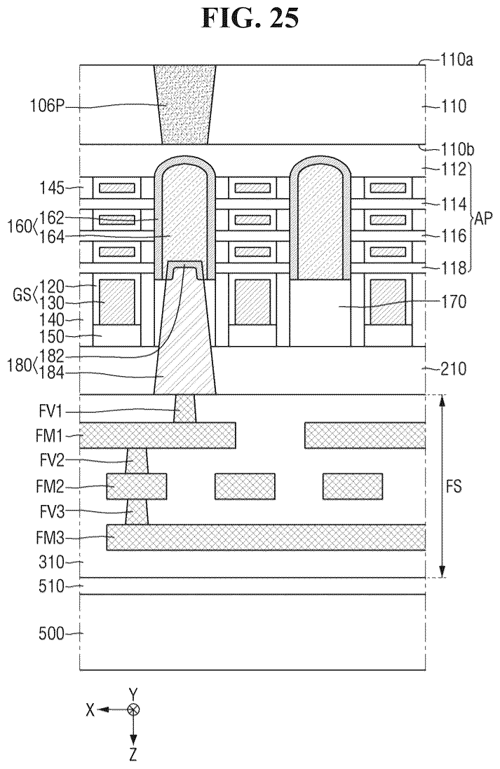

Referring to FIG. 25, the first base layer 110 is formed on the buffer layer 112 and the sacrificial contact pattern 106P (e.g., formed directly thereon).

In an embodiment, the first base layer 110 may include an insulating material having an etch selectivity different from that of the sacrificial contact pattern 106P. For example, in an embodiment the first base layer 110 may include at least one compound selected from silicon oxide, silicon oxynitride, silicon oxycarbonitride, and combinations thereof. However, embodiments of the present disclosure are not necessarily limited thereto. In an embodiment, the first base layer 110 may include a silicon oxide film.

The first base layer 110 may replace the second base layer 108 so as to surround the sacrificial contact pattern 106P. For example, in an embodiment a silicon oxide layer covering the sacrificial contact pattern 106P may be formed, and a planarization process may be performed on the silicon oxide layer to expose an upper surface of the sacrificial contact pattern 106P. Thus, the first base layer 110 covering the upper surface of the buffer layer 112 and the side surface of the sacrificial contact pattern 106P may be formed.

The first base layer 110 may include the first surface 110a and the second surface 110b that are opposite to each other (e.g., in the third direction Z). For example, as shown in an embodiment of FIG. 25, the first surface 110a may be an upper surface of the first base layer 110, and the second surface 110b may be a lower surface of the second base layer 108. As described above, since the width of the sacrificial contact pattern 106P may decrease as the sacrificial contact pattern 106P gets closer to the buffer layer 112, the width of the sacrificial contact pattern 106P may decrease as the sacrificial contact pattern 106P extends in direction from the first surface 110a to the second surface 110b.

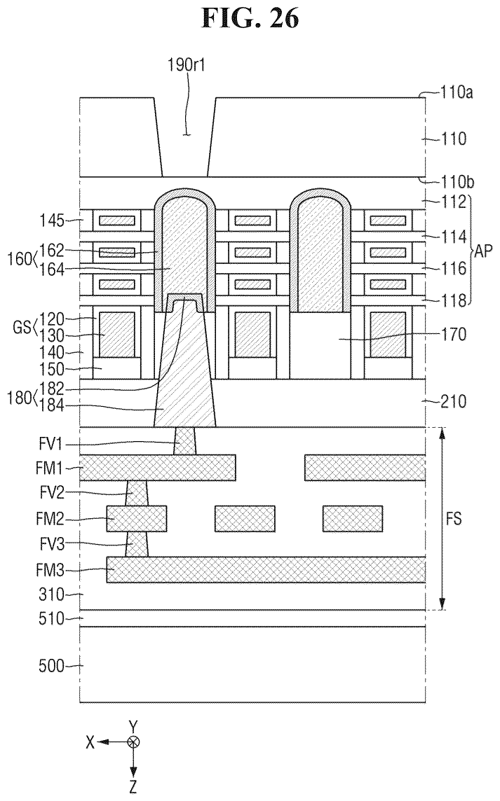

Referring to FIGS. 25 and 26, the sacrificial contact pattern 106P is removed.

As the sacrificial contact pattern 106P has been removed, a first contact hole 190r1 exposing a portion of the buffer layer 112 may be formed in the first base layer 110. As described above, the sacrificial contact pattern 106P may overlap the source/drain pattern 160 in the third direction Z. Thus, the first contact hole 190r1 may overlap with the source/drain pattern 160 in the third direction Z. For example, the first contact hole 190r1 may be disposed above and self-aligned with the source/drain pattern 160.

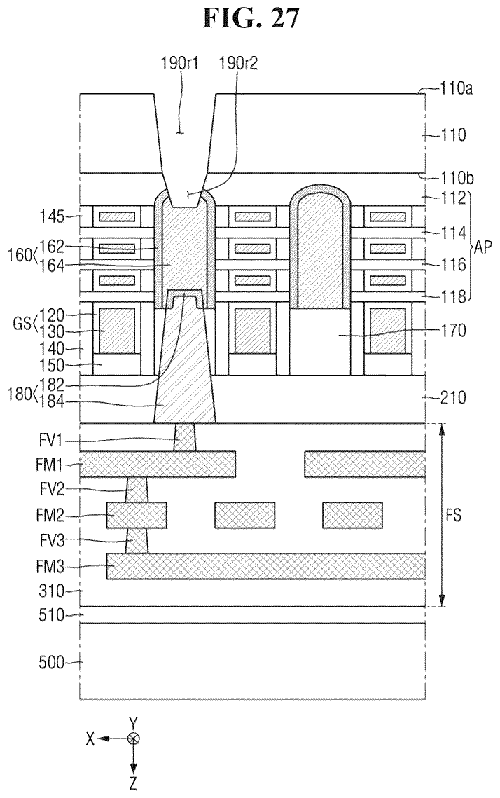

Referring to FIG. 27, a process of exposing the source/drain pattern 160 using the first contact hole 190r1 is performed.

For example, in an embodiment a second contact hole 190r2 exposing a portion of the source/drain pattern 160 disposed in the buffer layer 112 may be formed using the first contact hole 190r1 for alignment. In some embodiments, forming the first contact hole 190r1 and the second contact hole 190r2 may be performed in an in-situ manner.

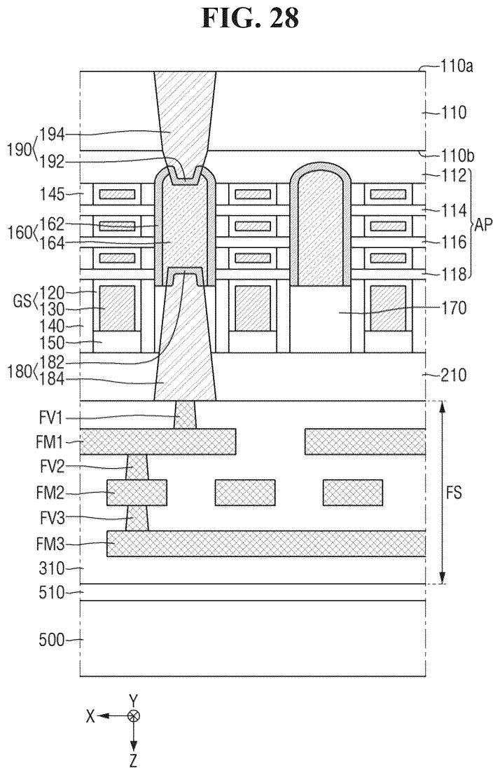

Referring to FIGS. 27 and 28, the lower source/drain contact 190 connected to (e.g., directly connected thereto) the source/drain pattern 160 is formed.

For example, the lower source/drain contact 190 may fill the first contact hole 190r1 and the second contact hole 190r2. Thus, the lower source/drain contact 190 replacing the sacrificial contact pattern 106P may be formed so as to be connected to the source/drain pattern 160. The lower source/drain contact 190 may extend through the first base layer 110 and the buffer layer 112 (e.g., in the third direction Z) so as to directly contact the source/drain pattern 160.

In some embodiments, the lower source/drain contact 190 may include the second silicide film 192 and the second metal film 194. In an embodiment, the second silicide film 192 may be formed by reacting an element included in the second metal film 194 with the source/drain pattern 160.

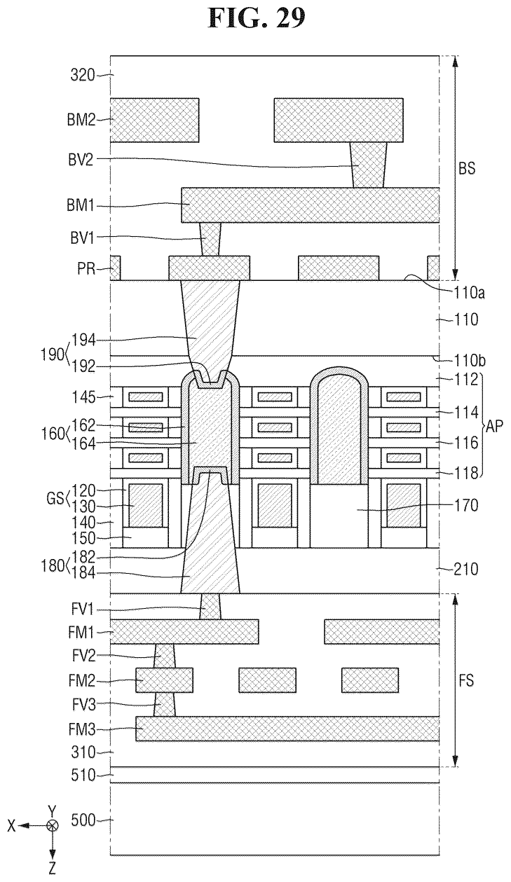

Referring to FIG. 29, the backside wiring structure BS is formed on the first surface 110a of the first base layer 110.

In an embodiment, the backside wiring structure BS may include the backside inter-wiring insulating film 320, the plurality of backside wiring patterns BM1 and BM2, and the plurality of backside via patterns BV1 and BV2.

In some embodiments, the backside wiring structure BS may include the power rail PR. The power rail PR may extend along the first surface 110a of the first base layer 110 so as to be connected to (e.g., directly connected thereto) the lower source/drain contact 190. As a result, the backside wiring structure BS may act as a power delivery network (PDN) for various electronic elements (e.g., a field effect transistor including the active pattern AP and the gate structure GS) formed on the second surface 110b of the first base layer 110.

Subsequently, referring to FIG. 2, the carrier substrate 500 and the oxide layer 510 are removed. As a result, the semiconductor device as described above with reference to FIGS. 1 to 5 may be manufactured.

As the semiconductor device is increasingly highly integrated, a width of each of the wiring patterns and the via patterns constituting the semiconductor device is gradually decreasing. Thus, a voltage drop (e.g., IR drop) of the power delivery network (PDN) supplying the power voltage to the electronic element has emerged as a critical issue.

The semiconductor device according to some embodiments may have a so-called backside power delivery network (BSPDN) to realize a reduced voltage drop. For example, as described above, the backside wiring structure BS acting as the power delivery network PDN may be disposed on the backside (e.g., the first surface 110a) of the first base layer 110 on which the electronic element (e.g., a field effect transistor including the active pattern AP and the gate structure GS) is not disposed. Thus, as compared to an embodiment in which the power delivery network PDN is disposed on the frontside (e.g., the second surface 110b of the first base layer 110), the semiconductor device according to some embodiments may reduce routing crosstalk to reduce the voltage drop and reduce a size of the device.

In one example, for a connection between the backside power delivery network (BSPDN) and the electronic element, a contact (hereinafter, referred to as a direct contact) that directly connects the backside power delivery network (BSPDN) and the electronic element to each other has been proposed. The direct contact can connect the backside power delivery network (BSPDN) and the electronic element to each other at the shortest path and thus is advantageous in terms of the PPAC (Power, Performance, Area, Cost). However, it may be difficult for the direct contact formed from the backside of the substrate (e.g., the first surface 110a of the first base layer 110) to be aligned with the electronic element.

However, in the semiconductor device according to some embodiments of the present disclosure, the lower source/drain contact 190 may be easily aligned with the electronic element (e.g., a field effect transistor including the active pattern AP and the gate structure GS). For example, as described above, the lower source/drain contact 190 may replace the sacrificial contact pattern 106P as formed previously so as to be connected to the source/drain pattern 160, and thus may be embodied as a self-aligned direct contact.

Further, in the semiconductor device manufacturing method according to some embodiments, the width of the sacrificial contact pattern 106P decreases as the sacrificial contact pattern 106P gets closer to the source/drain pattern 160, such that a void of the lower source/drain contact 190 may be effectively prevented. If the width of the sacrificial contact pattern 106P increases as the sacrificial contact pattern 106P gets closer to the source/drain pattern 160, the void may occur in the lower source/drain contact 190 because an opening used to fill the contact holes (e.g., the first contact hole 190r1 and the second contact hole 190r2) is narrow in the process of forming the lower source/drain contact 190 replacing the sacrificial contact pattern 106P.

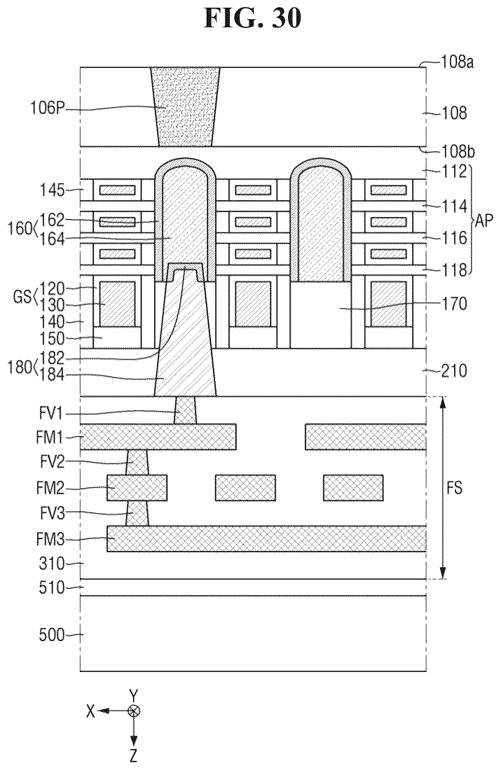

FIGS. 30 to 33 are diagrams of intermediate structures corresponding to intermediate steps for illustrating a method for manufacturing a semiconductor device according to some embodiments. For convenience of description, descriptions duplicate with those as set forth above with reference to FIGS. 1 to 29 may be briefly set forth or omitted. For reference, FIG. 30 is a diagram of an intermediate structure to illustrate a step after FIG. 23.

Referring to FIGS. 23 and 30, the second base layer 108 and the sacrificial contact pattern 106P are exposed.

For example, the etch stop film 102 may be removed. The buffer substrate 104 may then be removed. Thus, the upper surface of the second base layer 108 and the upper surface of the sacrificial contact pattern 106P may be exposed.

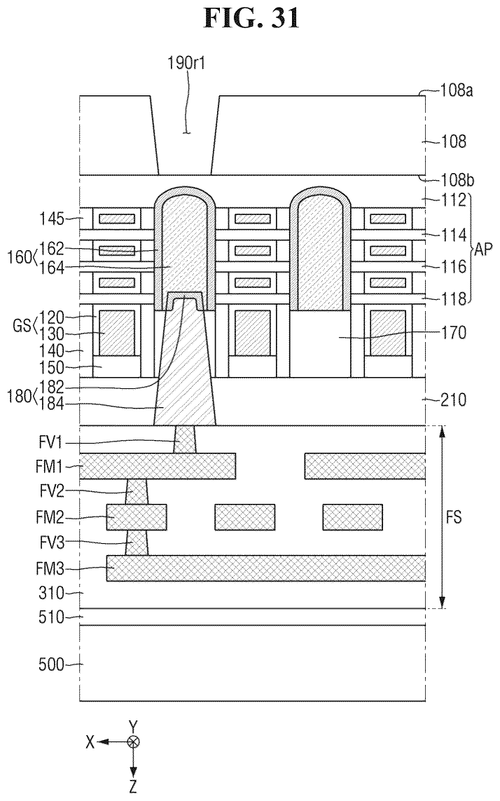

Referring to FIG. 31, the sacrificial contact pattern 106P is removed.

As described above, since the sacrificial contact pattern 106P may have an etch selectivity different from that of the second base layer 108, the sacrificial contact pattern 106P may be selectively removed. As the sacrificial contact pattern 106P has been removed, the first contact hole 190r1 exposing a portion of the buffer layer 112 may be formed in the second base layer 108.

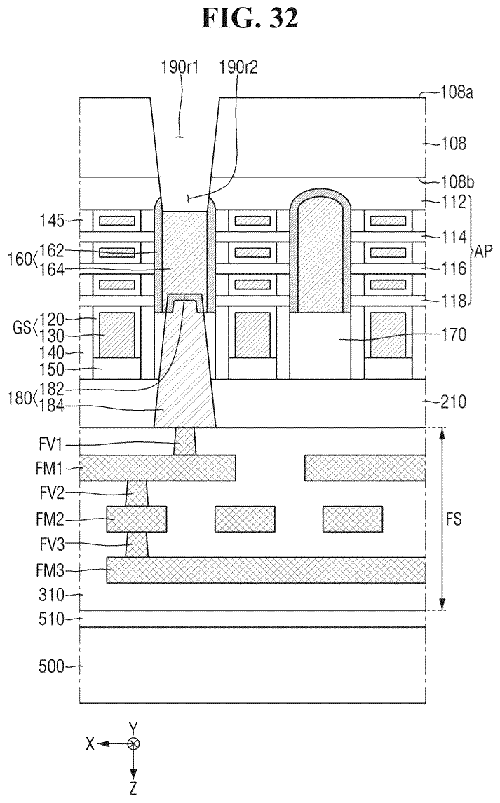

Referring to FIG. 32, the second contact hole 190r2 is formed. Forming the second contact hole 190r2 may be similar to that as described above with reference to FIG. 27. Thus, a detailed description thereof is omitted below for economy of description.

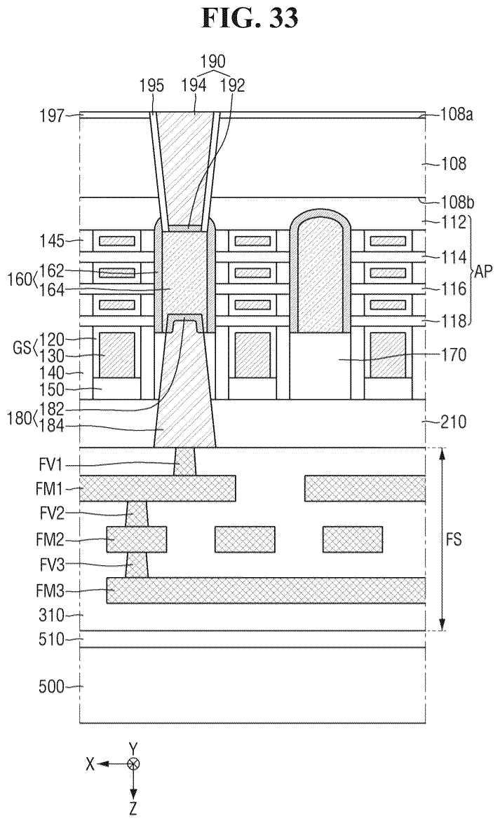

Referring to FIG. 33, the lower source/drain pattern 160 is formed. Forming the lower source/drain pattern 160 may be similar to that as described above with reference to FIG. 28. Thus, a detailed description thereof is omitted below for economy of description.

In some embodiments, the contact spacer 195 may be further formed on the side surface of the lower source/drain contact 190. The contact spacer 195 may extend along the side surface of the lower source/drain contact 190.

In some embodiments, the isolation insulating film 197 may be further formed on the third surface 108a of the second base layer 108. The isolation insulating film 197 may extend along the third surface 108a of the second base layer 108.

Subsequently, the steps as described above with reference to FIGS. 29 and 2 may be performed. As a result, the semiconductor device as described above with reference to FIG. 7 may be manufactured.

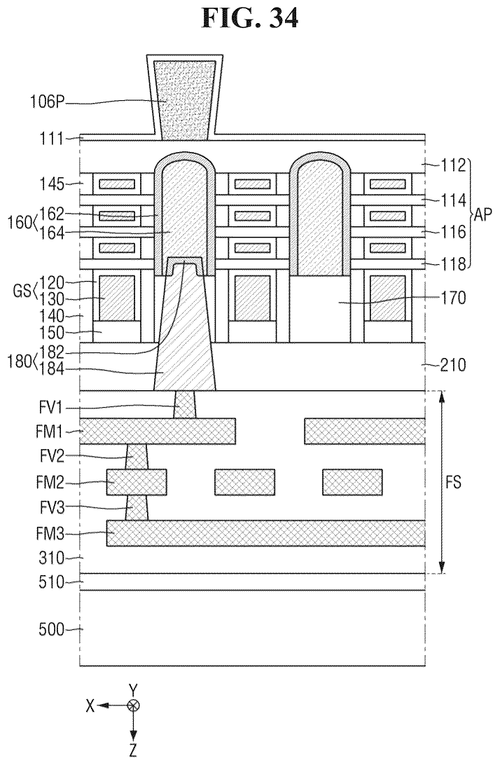

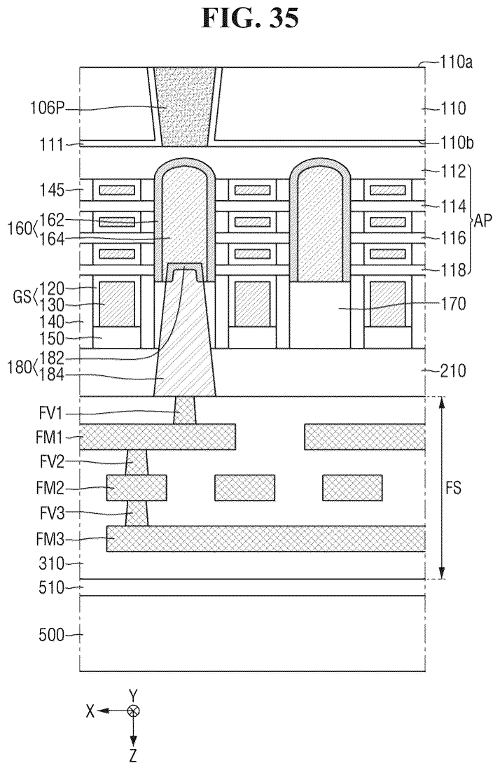

FIGS. 34 and 35 are diagrams of intermediate structures corresponding to intermediate steps for illustrating a method for manufacturing a semiconductor device according to some embodiments. For convenience of description, descriptions duplicate with those as set forth above with reference to FIGS. 1 to 29 are briefly set forth or omitted. For reference, FIG. 34 is a diagram of an intermediate structure to illustrate a step after FIG. 24.

Referring to FIG. 34, the liner film 111 is formed on (e.g., formed directly thereon) the buffer layer 112 and the sacrificial contact pattern 106P.

The liner film 111 may extend along the upper surface of the buffer layer 112 and the side surface and the upper surface of the lower source/drain contact 190. In an embodiment, the liner film 111 may include an insulating material, for example, at least one compound selected from silicon oxide, silicon nitride, silicon oxynitride, or combinations thereof. However, embodiments of the present disclosure are not necessarily limited thereto. In an embodiment, the liner film 111 may include a silicon nitride film.

Referring to FIG. 35, the first base layer 110 is formed on the liner film 111.

The first base layer 110 may surround the sacrificial contact pattern 106P. For example, in an embodiment a silicon oxide layer covering the liner film 111 may be formed, and a planarization process may be performed on the silicon oxide layer to expose an upper surface of the sacrificial contact pattern 106P. Thus, the first base layer 110 covering the upper surface of the liner film 111 and the side surface of the liner film 111 may be formed.

Subsequently, the steps as described above with reference to FIGS. 26 to 29, and FIG. 2 may be performed. As a result, the semiconductor device as described above with reference to FIG. 8 may be manufactured.

In concluding the detailed description, those skilled in the art will appreciate that many variations and modifications may be made to the described embodiments without substantially departing from the principles of the present disclosure. Therefore, the described embodiments of the present disclosure are used in a generic and descriptive sense only and not for purposes of limitation.

What is claimed is:

1. A method for manufacturing a semiconductor device, the method comprising:
providing a buffer substrate;
forming a sacrificial contact film on the buffer substrate;
forming a sacrificial contact pattern by patterning the sacrificial contact film;
forming a first base layer on the buffer substrate, the first base layer surrounding the sacrificial contact pattern;
forming an active pattern on the first base layer and the sacrificial contact pattern, the active pattern extending in a first direction parallel to an upper surface of the first base layer;
forming a gate electrode on the active pattern, the gate electrode extending in a second direction intersecting the first direction and parallel to the upper surface of the first base layer;
forming a source/drain pattern on a side surface of the gate electrode, the source/drain pattern is directly connected to the active pattern, wherein the source/drain pattern overlaps the sacrificial contact pattern in a third direction intersecting the first direction and the second direction and perpendicular to the upper surface of the first base layer;
exposing the sacrificial contact pattern by removing the buffer substrate; and
forming a lower source/drain contact directly connected to the source/drain pattern by replacing the exposed sacrificial contact pattern.

2. The method of claim 1, wherein the forming of the sacrificial contact film includes performing an epitaxial growth process using the buffer substrate as a seed layer.

3. The method of claim 2, wherein:
the buffer substrate includes a silicon (Si) layer; and
the sacrificial contact film includes a silicon germanium (SiGe) layer.

4. The method of claim 1, wherein the forming of the first base layer includes:
forming a second base layer surrounding the sacrificial contact pattern by performing an epitaxial growth process using the buffer substrate and the sacrificial contact pattern as a seed layer; and
replacing the second base layer with the first base layer after exposing the sacrificial contact pattern by removing the buffer substrate.

5. The method of claim 4, wherein the sacrificial contact pattern and the second base layer have different etch selectivities from each other.

6. The method of claim 5, wherein:
the sacrificial contact pattern includes a silicon germanium (SiGe) layer; and
the second base layer includes a silicon (Si) layer.

7. The method of claim 4, wherein the first base layer includes an insulating material having an etch selectivity that is different from an etch selectivity of the sacrificial contact pattern.

8. The method of claim 1, further comprising:
the first base layer includes a first surface and a second surface opposite to each other in the third direction;
forming a backside wiring pattern on the first surface of the first base layer, the backside wiring pattern is directly connected to the lower source/drain contact,
and
the active pattern is disposed on the second surface of the first base layer.

9. The method of claim 1, wherein:
the active pattern includes a plurality of channel patterns spaced apart from each other in the third direction; and
each of the plurality of channel patterns extends in the first direction to penetrate the gate electrode.

10. A method for manufacturing a semiconductor device, the method comprising:
providing a buffer substrate;
forming a first base layer on the buffer substrate, wherein the first base layer includes a first surface facing the buffer substrate and a second surface opposite to the first surface;
forming a sacrificial contact pattern in the first base layer, the sacrificial contact pattern extending from the first surface towards the second surface, wherein a width of the sacrificial contact pattern decreases as the sacrificial contact pattern gets closer to the second surface;
forming an active pattern on the second surface of the first base layer, the active pattern extending in a first direction parallel to an upper surface of the first base layer;
forming a gate electrode on the active pattern, the gate electrode extending in a second direction intersecting the first direction and parallel to the upper surface of the first base layer;
forming a source/drain pattern on a side surface of the gate electrode, the source/drain pattern is directly connected to the active pattern, wherein the source/drain pattern overlaps the sacrificial contact pattern in a third direction intersecting the first direction and the second direction and perpendicular to the upper surface of the first base layer;
exposing the sacrificial contact pattern by removing the buffer substrate; and
forming a lower source/drain contact that is directly connected to the source/drain pattern by replacing the exposed sacrificial contact pattern.

11. The method of claim 10, wherein a thickness of the sacrificial contact pattern is in a range of about 1 nm to about 500 nm.

12. The method of claim 10, wherein the sacrificial contact pattern includes a silicon germanium (SiGe) layer.

13. The method of claim 12, wherein the sacrificial contact pattern further comprises impurities including at least one compound selected from a group consisting of carbon (C), boron (B), arsenic (As), phosphorus (P), antimony (Sb), gallium (Ga), and tin (Sn).

14. The method of claim 10, further comprising:
forming a buffer layer between the first base layer and the active pattern, the buffer layer extending in the first direction,
wherein the lower source/drain contact extends through the buffer layer to be directly connected to the source/drain pattern.

15. The method of claim 14, wherein a thickness of the buffer layer is in a range of about 1 nm to about 500 nm.

16. The method of claim 10, further comprising forming a backside wiring pattern on the first surface of the first base layer, the backside wiring pattern is directly connected to the lower source/drain contact.

17. A method for manufacturing a semiconductor device, the method comprising:
providing a buffer substrate;
forming a sacrificial contact film on the buffer substrate;
forming a sacrificial contact pattern by patterning the sacrificial contact film;
forming a first base layer surrounding a side surface of the sacrificial contact pattern, wherein the first base layer includes a first surface facing the buffer substrate and a second surface opposite to the first surface;
forming an active pattern on the second surface of the first base layer, the active pattern extending in a first direction parallel to an upper surface of the first base layer;
forming a gate electrode extending in a second direction intersecting the first direction and parallel to the upper surface of the first base layer, the gate electrode penetrating the active pattern;
forming a source/drain pattern on a side surface of the gate electrode, the source/drain pattern is directly connected to the active pattern, wherein the source/drain pattern overlaps the sacrificial contact pattern in a third direction intersecting the first direction and the second direction and perpendicular to the upper surface of the first base layer;
forming a frontside wiring pattern on the second surface of the first base layer, the frontside wiring pattern is electrically connected to the gate electrode and the source/drain pattern;
exposing the sacrificial contact pattern by removing the buffer substrate;
forming a lower source/drain contact directly connected to the source/drain pattern by replacing the exposed sacrificial contact pattern with a lower source/drain contact; and
forming a backside wiring pattern on the first surface of the first base layer, the backside wiring pattern is directly connected to the lower source/drain contact.

18. The method of claim 17, wherein the sacrificial contact film includes a silicon germanium (SiGe) layer.

19. The method of claim 17, wherein the forming of the first base layer includes:
forming a second base layer surrounding the sacrificial contact pattern by performing an epitaxial growth process using the buffer substrate and the sacrificial contact pattern as a seed layer; and
replacing the second base layer with the first base layer after exposing the sacrificial contact pattern by removing the buffer substrate.

20. The method of claim 17, wherein forming the lower source/drain contact includes:
forming a first contact hole by removing the sacrificial contact pattern;
forming a second contact hole using the first contact hole for alignment, wherein the second contact hole exposes the source/drain pattern; and
forming the lower source/drain contact filling the first contact hole and the second contact hole.
